(19) United States
(12) Patent Application Publication
(10) Pub. No.: US 2026/0170190 A1
(43) Pub. Date: Jun. 18, 2026

(54) INTEGRATED SOFTWARE SYSTEM FOR MULTI-PURPOSE COMPUTER-AIDED DESIGN

(71) Applicant: IronCAD, LLC, Atlanta, GA (US)

(72) Inventors: Yawei Li, ATLANTA, GA (US); Tao Yang Han, ATLANTA, GA (US)

(21) Appl. No.: 18/985,307

(22) Filed: Dec. 18, 2024

(51) Int. Cl. G06F 30/13

(52) U.S. Cl. CPC G06F 30/13

(57) ABSTRACT

An integrated system with computer-aided design (CAD) software and a computer-implemented method of generating a top-down hierarchical space design on the integrated system are provided. The system receives instructions to create region geometries of the top-down hierarchical space design, and generates the region geometries according to the instructions. The system may receive a modification instruction to apply a region modifier to a corresponding region geometry, and modify the corresponding region geometry according to the modification instruction to generate a modified region geometry. In the top-down hierarchical space design, the region geometries include a first region geometry, which represents a top-level space, and at least one second region geometry, which is a child region geometry of a parent region geometry. The child region geometry may be generatively generated by applying a region operator to the parent region geometry, or may be interactively generated based on a manual instruction.

### FIELD OF THE INVENTION

The present invention relates generally to computer-aided design (CAD) methods and software applications, and more particularly to an integrated software system for multi-purpose CAD.

### BACKGROUND OF THE INVENTION

The background description provided herein is for the purpose of generally presenting the context of the present invention. The subject matter discussed in the background of the invention section should not be assumed to be prior art merely as a result of its mention in the background of the invention section. Similarly, a problem mentioned in the background of the invention section or associated with the subject matter of the background of the invention section should not be assumed to have been previously recognized in the prior art. The subject matter in the background of the invention section merely represents different approaches, which in and of themselves may also be inventions.

The computer has greatly affected essentially all forms of information management, including the geometric modeling arts. Nowadays there are numerous computer program products that allow the user to create, store, and modify geometric models and their graphical renderings of various types on a display screen, and to print or otherwise output such geometric models and their renderings. Currently, an existing design system may utilize a standard generative approach with a software program which, based on user defined inputs, to generate a certain number of outputs. However, such a process in the existing design system is unidirectional, and changes cannot be directly made to the outputs without breaking the higher level parametrization and rules that define the generative process. To modify the outputs and maintain the relationship and consistency of the defined parametrization and rules, a user must change the input parameters and rules, and re-execute the generative design process to create new outputs. Therefore, a heretofore unaddressed need exists in the art to address the aforementioned deficiencies and inadequacies.

### SUMMARY OF THE INVENTION

One aspect of the present invention relates to a computer-implemented method of generating a top-down hierarchical space design on an integrated system with computer-aided design (CAD) software. In certain embodiments, the computer-implemented method includes: receiving instructions to create a plurality of region geometries of the top-down hierarchical space design; generating the region geometries according to the instructions; receiving a modification instruction to apply a region modifier to a corresponding one of the region geometries; and modifying the corresponding one of the region geometries according to the modification instruction to generate a modified region geometry. The region geometries include a first region geometry and at least one second region geometry, the first region geometry represents a top-level space in the top-down hierarchical space design, each of the at least one second region geometry is a child region geometry of a parent region geometry, and the parent region geometry is the top region geometry or another one of the at least one second region geometry.

In another aspect, an integrated system with CAD software is provided. The integrated system includes a processor and a storage device storing computer executable code. The computer executable code, when executed at the processor, is configured to provide the CAD software, and to: receive instructions to create a plurality of region geometries of a top-down hierarchical space design; generate the region geometries according to the instructions; receive a modification instruction to apply a region modifier to a corresponding one of the region geometries; and modify the corresponding one of the region geometries according to the modification instruction to generate a modified region geometry. The region geometries include a first region geometry and at least one second region geometry, the first region geometry represents a top-level space in the top-down hierarchical space design, each of the at least one second region geometry is a child region geometry of a parent region geometry, and the parent region geometry is the top region geometry or another one of the at least one second region geometry.

In certain embodiments, a specific region geometry of the region geometries includes: a feature history list including an initial feature of the specific region geometry, and information related to a shape representation of the specific region geometry. In one embodiment, the shape representation of the specific region geometry is a boundary representation (B-rep).

In certain embodiments, the region modifier, when being applied to the corresponding one of the region geometries, is configured to apply a geometrical feature to the corresponding one of the region geometries to generate the modified region geometry. In one embodiment, the method further includes: updating the feature history list of the modified region geometry by appending the geometrical feature to the feature history list of the corresponding one of the region geometries; wherein for the modified region geometry, the initial feature and the appended geometrical feature are preserved in the updated feature history list.

In certain embodiments, the region modifier, when being applied to the corresponding one of the region geometries, is configured to change a definition of the corresponding one of the region geometries to generate the modified region geometry, and the feature history list of the modified region geometry is not updated.

In certain embodiments, the child region geometry is generatively generated by: receiving an operator instruction to apply a region operator to the parent region geometry; and applying the region operator to the parent region geometry to generate the child region geometry.

In certain embodiments, the method further includes: receiving an operator definition instruction to define the region operator; and defining the region operator according to the operator definition instruction.

In certain embodiments, the region operator is: a horizontal slicer, a vertical slicer, a grid divider, a concentric divider, a scaler, or a custom-defined operator.

In certain embodiments, the method further includes: receiving the modification instruction to apply the region modifier to the region operator; and modifying the region operator according to the modification instruction to generate a modified region operator. In one embodiment, the method further includes: re-applying the modified region operator to the parent region geometry to generate the modified child region geometry.

In certain embodiments, the method further includes: receiving the modification instruction to apply the region modifier to the child region geometry; and modifying the child region geometry according to the modification instruction to generate a modified child region geometry. In one embodiment, the region modifier is configured to apply a geometrical feature to the child region geometry to generate the modified child region geometry. In one embodiment, the method further includes: updating the feature history list of the modified child region geometry by appending the geometrical feature to the feature history list of the child region geometry; wherein for the modified child region geometry, the initial feature and the appended geometrical feature are preserved in the updated feature history list.

In certain embodiments, the method further includes: receiving the modification instruction to apply the region modifier to the parent region geometry; modifying the parent region geometry according to the modification instruction to generate a modified parent region geometry; and re-applying the region operator to the modified parent region geometry to generate a modified child region geometry. In one embodiment, the region modifier is configured to apply a geometrical feature to the parent region geometry to generate the modified parent region geometry. In one embodiment, the method further includes: updating the feature history list of the modified parent region geometry by appending the geometrical feature to the feature history list of the parent region geometry; wherein for the modified parent region geometry, the initial feature and the appended geometrical feature are preserved in the updated feature history list. In another embodiment, the region modifier is configured to change a definition of the parent region geometry to generate the modified parent region geometry, and the feature history list of the modified parent region geometry and the feature history list of the modified child region geometry are not updated.

In certain embodiments, each of the first region geometry and the child region geometry is interactively generated based on a manual instruction provided by a user. In one embodiment, the method further includes: receiving the modification instruction to apply the region modifier to the parent region geometry; and modifying the parent region geometry according to the modification instruction to generate a modified parent region geometry. The child region geometry being interactively generated is not updated according to the modification instruction to the parent region geometry.

In one embodiment, the method further includes: receiving the modification instruction to apply the region modifier to the child region geometry; and modifying the child region geometry according to the modification instruction to generate a modified child region geometry. In one embodiment, the region modifier is configured to apply a geometrical feature to the child region geometry to generate the modified child region geometry. In one embodiment, the method further includes: updating the feature history list of the modified child region geometry by appending the geometrical feature to the feature history list of the child region geometry, wherein for the modified child region geometry, the initial feature and the appended geometrical feature are preserved in the updated feature history list. In another embodiment, the region modifier is configured to change a definition of the child region geometry to generate the modified child region geometry, and the feature history list of the modified child region geometry is not updated.

In one embodiment, the method further includes: receiving the modification instruction to apply the region modifier to the top region geometry; and modifying the top region geometry according to the modification instruction to generate a modified top region geometry. In one embodiment, the region modifier is configured to apply a geometrical feature to the top region geometry to generate the modified top region geometry. In one embodiment, the method further includes: updating the feature history list of the modified top region geometry by appending the geometrical feature to the feature history list of the top region geometry, wherein for the modified top region geometry, the initial feature and the appended geometrical feature are preserved in the updated feature history list. In another embodiment, the region modifier is configured to change a definition of the top region geometry to generate the modified top region geometry, and the feature history list of the modified top region geometry is not updated.

In certain embodiments, the method further includes: combining the top-down hierarchical space design with a hierarchical assembly structure. The hierarchical assembly structure includes a plurality of assemblies, the assemblies include a top assembly and at least one sub-assembly, and the assemblies of the hierarchical assembly structure are associated to the region geometries of the top-down hierarchical space design.

In certain embodiments, the method further includes: in response to modifying the corresponding one of the region geometries according to the modification instruction, adjusting a corresponding assembly of the assemblies of the hierarchical assembly structure associated with the corresponding one of the region geometries according to the modified region geometry.

In certain embodiments, the method further includes: defining a relationship between design objects contained in a corresponding assembly of the assemblies of the hierarchical assembly structure and the corresponding one of the region geometries associated with the corresponding assembly.

In one embodiment, the relationship between the design objects contained in the corresponding assembly and the corresponding one of the region geometries associated with the corresponding assembly includes: defining the corresponding one of the region geometries associated with the corresponding assembly as a bounding region of the design objects; defining a geometry of the design objects to depend on the corresponding one of the region geometries associated with the corresponding assembly; defining positions of the design objects to depend on the corresponding one of the region geometries associated with the corresponding assembly; or defining the corresponding one of the region geometries associated with the corresponding assembly as an influence region of the design objects.

In one embodiment, in response to modifying the corresponding one of the region geometries associated with the corresponding assembly according to the modification instruction, adjusting the corresponding assembly and the design objects contained in the corresponding assembly according to the modified region geometry.

In certain embodiments, the first region geometry of the top-down hierarchical space design is associated to the top assembly or a corresponding sub-assembly of the assemblies of the hierarchical assembly structure.

In certain embodiments, the top assembly of the hierarchical assembly structure is associated to the first region geometry or a corresponding second region geometry of the region geometries of the top-down hierarchical space design.

These and other aspects of the present invention will become apparent from the following description of the preferred embodiments, taken in conjunction with the following drawings, although variations and modifications therein may be affected without departing from the spirit and scope of the novel concepts of the disclosure.

### BRIEF DESCRIPTION OF THE DRAWINGS

The accompanying drawings illustrate one or more embodiments of the invention and, together with the written description, serve to explain the principles of the invention. The same reference numbers may be used throughout the drawings to refer to the same or like elements in the embodiments.

FIG. 1 schematically shows an integrated software system for multi-purpose CAD according to certain embodiments of the present invention.

FIG. 2 schematically shows the operation of the integrated software system of FIG. 1 according to certain embodiments of the present invention.

FIGS. 3A to 3H schematically show a process of generating and modifying the region geometries of a top-down hierarchical space design according to certain embodiments of the present invention.

FIG. 4 schematically shows an alternative process of modifying the region geometry of the top-down hierarchical space design from FIG. 3D according to certain embodiments of the present invention.

FIGS. 5A and 5B schematically show another alternative process of modifying the region operator and the region geometry of the top-down hierarchical space design from FIG. 3G according to certain embodiments of the present invention.

FIG. 6 schematically shows yet another alternative process of modifying the region geometry of the top-down hierarchical space design from FIG. 3G according to certain embodiments of the present invention.

FIG. 7A schematically shows a hierarchical assembly structure according to certain embodiments of the present invention.

FIG. 7B schematically shows combining the top-down hierarchical space design of FIG. 3D with the hierarchical assembly structure of FIG. 7A according to certain embodiments of the present invention.

FIGS. 8A and 8B schematically shows the adjustment to a sub-assembly by applying a region modifier to the corresponding region geometry according to certain embodiments of the present invention.

FIGS. 9A to 9C schematically show a process of generating a top-down hierarchical space design combined with a hierarchical assembly structure according to certain embodiments of the present invention.

FIGS. 10A to 10C schematically show a process of associating a hierarchical assembly structure to multiple top-down hierarchical space designs according to certain embodiments of the present invention.

### DETAILED DESCRIPTION OF THE INVENTION

The invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this invention will be thorough and complete, and will fully convey the scope of the invention to those skilled in the art. Like reference numerals refer to like elements throughout.

The terms used in this specification generally have their ordinary meanings in the art, within the context of the invention, and in the specific context where each term is used. Certain terms that are used to describe the invention are discussed below, or elsewhere in the specification, to provide additional guidance to the practitioner regarding the description of the invention. For convenience, certain terms may be highlighted, for example using italics and/or quotation marks. The use of highlighting has no influence on the scope and meaning of a term; the scope and meaning of a term is the same, in the same context, whether or not it is highlighted. It will be appreciated that same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and in no way limits the scope and meaning of the invention or of any exemplified term. Likewise, the invention is not limited to various embodiments given in this specification.

It will be understood that, as used in the description herein and throughout the claims that follow, the meaning of “a”, “an”, and “the” includes plural reference unless the context clearly dictates otherwise. Also, it will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

Furthermore, relative terms, such as “lower” or “bottom” and “upper” or “top,” may be used herein to describe one element's relationship to another element as illustrated in the figures. It will be understood that relative terms are intended to encompass different orientations of the device in addition to the orientation depicted in the figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

It will be further understood that the terms “comprises” and/or “comprising,” or “includes” and/or “including” or “has” and/or “having”, or “carry” and/or “carrying,” or “contain” and/or “containing,” or “involve” and/or “involving, and the like are to be open-ended, i.e., to mean including but not limited to. When used in this invention, they specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present invention, and will not be interpreted in an idealized or overly formal sense unless expressly so defined herein.

As used herein, the phrase at least one of A, B, and C should be construed to mean a logical (A or B or C), using a non-exclusive logical OR. As used herein, the term “and/or” includes any and all combinations of one or more of the associated listed items. The apparatuses and methods will be described in the following detailed description and illustrated in the accompanying drawings by various blocks, components, circuits, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system. By way of example, an element, or any portion of an element, or any combination of elements may be implemented as a “processing system” that includes one or more processors.

The description below is merely illustrative in nature and is in no way intended to limit the invention, its application, or uses. The broad teachings of the invention can be implemented in a variety of forms. Therefore, while this invention includes particular examples, the true scope of the invention should not be so limited since other modifications will become apparent upon a study of the drawings, the specification, and the following claims. For purposes of clarity, the same reference numbers will be used in the drawings to identify similar elements. It should be understood that one or more steps within a method may be executed in different order (or concurrently) without altering the principles of the invention.

As used herein, the term “computer-aided design software” or its abbreviation “CAD software” may refer to computer-aided design software and any other design collaboration software, such as space planning, architecture, computer-aided engineering (CAE), or game features that include geometric modeling of components or similar actions.

As used herein, the term “module” may refer to, be part of, or include suitable software components that provide the described functionality. In certain embodiments, the term module may include both software components, such as codes, and hardware components that execute the codes.

The term “code”, as used herein, may include software, firmware, and/or microcode, and may refer to programs, routines, functions, classes, and/or objects. The term “shared”, as used herein, means that some or all code from multiple hardware modules may be executed using a single (shared) processor. In addition, some or all code from multiple hardware modules may be stored by a single (shared) memory. The term “group”, as used herein, means that some or all code from a single hardware module may be executed using a group of processors. In addition, some or all code from a single hardware module may be stored using a group of memories.

As used herein, the term “region geometry” refers to a geometric representation of the shape of a spatial region in a top-down hierarchical space design. A region geometry may be a simple shape such as a box or sphere, a complicated shape representation such as a boundary representation (B-Rep) in a CAD system, or a feature history representing how a shape is constructed by executing a list of features. One embodiment of a region geometry is a list of feature history and the resulting B-Rep representation.

As used herein, the term “region hierarchy” refers to a hierarchical structure of the region geometries in the form of parent-child relationships. A region geometry may have zero or any number of child region geometry, which makes the region geometry a “parent” region geometry. A child region geometry may have dependency of its parent region geometry. On the other hand, a child region geometry may be completely independent from its parent region geometry.

As used herein, the term “region operator” refers to a generative operator being used to generate one or more child region geometries from a parent region geometry. One embodiment of child-parent region geometry dependency could be that one or multiple number of the child region geometry are generatively created from a parent region geometry by applying a region operator to the parent region geometry. In such case, the parent region geometry remembers the region operator. The initial shape of a child region geometry which is created by a region operator is maintained as the first feature of that child region geometry.

As used herein, the term “region modifier” is a modifier being applied to modify a region geometry and/or a region operator. In certain embodiments, a region geometry may be modified by a region modifier after the initial creation of the region geometry, whether it is independently created or created from a parent region geometry by applying a region operator. One embodiment of a region modifier is to apply one or multiple features to the original region geometry, such that the region geometry is modified with the feature(s) applied to become a modified region geometry. If a region geometry is modified by a region modifier, a history of such features applied by the region modifier is maintained with the modified region geometry. The history of such features will be appended to the original feature list of the modified region geometry. Another embodiment of a region modifier is to directly modify the definition of the region geometry and/or the region operator, such that the definition of the region geometry/region operator is changed by the region modifier. In this case, the history of the region geometry is not affected.

As discussed above, an existing design system may utilize a standard generative approach with a software program which, based on user defined inputs, to generate a certain number of outputs. However, such a process in the existing design system is unidirectional, and changes cannot be directly made to the outputs without breaking the higher level parametrization and rules that define the generative process. To modify the outputs and maintain the relationship and consistency of the defined parametrization and rules, a user must change the input parameters and rules, and re-execute the generative design process to create new outputs. The existing system does not allow a user to specifically create child envelope geometry from parent envelop geometry, or to preserve the changes made to outputs, such as envelope geometry and 3D models, after an execution or re-execution of generative design process. The existing system also has no capability to combine generative design and interactive design methods to maximize the flexibility in space design and product design.

In view of the deficiencies in the existing system, it is desirable to provide an integrated system with the CAD software to maximize design flexibility by combining generative design and interactive design methods. Specifically, maximum design flexibility can be achieved by applying such combined methods in the initial creation of outputs as well as in the modification processes. The integrated system may also provide direct modifications to the outputs or modifications to the input parameters and rules then re-execute the generative design process, thus allowing any mix of these two approaches of design modifications. In addition, while performing design in such combined approaches, the modifications made to the inputs as well as directly to the outputs, including but not limited to the region geometry and 3D objects, are all preserved after re-execution of the generative design process.

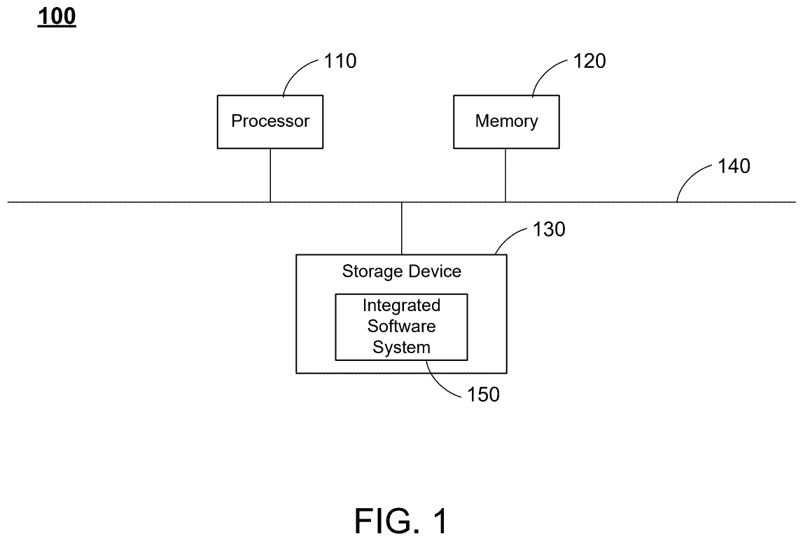

FIG. 1 schematically shows an integrated software system for multi-purpose CAD according to certain embodiments of the present invention. As shown in FIG. 1, the integrated software system 100 (hereinafter the system 100) is in the form of a computing device, which includes a processor 110, a memory 120, and a storage device 130, and a bus 140 interconnecting the processor 110, the memory 120 and the storage device 130. In one embodiment, the processor 110, the memory 120 and the storage device 130 may be in the form of a general computer, a specialized computer, or other types of computing devices. In certain embodiments, the system 100 may include necessary hardware and/or software components (not shown) to perform its corresponding tasks. Examples of these hardware and/or software components may include, but not limited to, other required memory modules, network ports, interfaces, buses, Input/Output (I/O) modules and peripheral devices, and details thereof are not elaborated herein.

The processor 110 controls operation of the system 100, which may be used to execute any computer executable code or instructions. In certain embodiments, the processor 110 may be a central processing unit (CPU), and the computer executable code or instructions being executed by the processor 110 may include an operating system (OS) and other applications, codes or instructions stored in the system 100. In certain embodiments, the system 100 may run on multiple processors, which may include any suitable number of processors.

The memory 120 may be a volatile memory module, such as the random-access memory (RAM), for storing the data and information during the operation of the system 100. In certain embodiments, the memory 120 may be in the form of a volatile memory array. In certain embodiments, the system 100 may run on more than one memory 120.

The storage device 130 is a non-volatile storage media or device for storing the computer executable code or instructions, such as the OS and the software applications for the system 100. Examples of the storage device 130 may include hard drives, flash memory, memory cards, USB drives, or other types of non-volatile storage devices such as floppy disks, optical drives, or any other types of data storage devices. In certain embodiments, the system 100 may have more than one storage device 130, and the software applications of the system 100 may be stored in the more than one storage device 130 separately.

As shown in FIG. 1, the computer executable code or instructions stored in the storage device 130 may include an integrated software system 150 for multi-purpose CAD. Specifically, the integrated software system 150, when executed at the processor 110, not only provides the typical CAD features, such as generating an assembly structure with parts and/or sub-assemblies, but also allows a top-down hierarchical space design feature for performing specific designs, such as space design or other types of top-down designs.

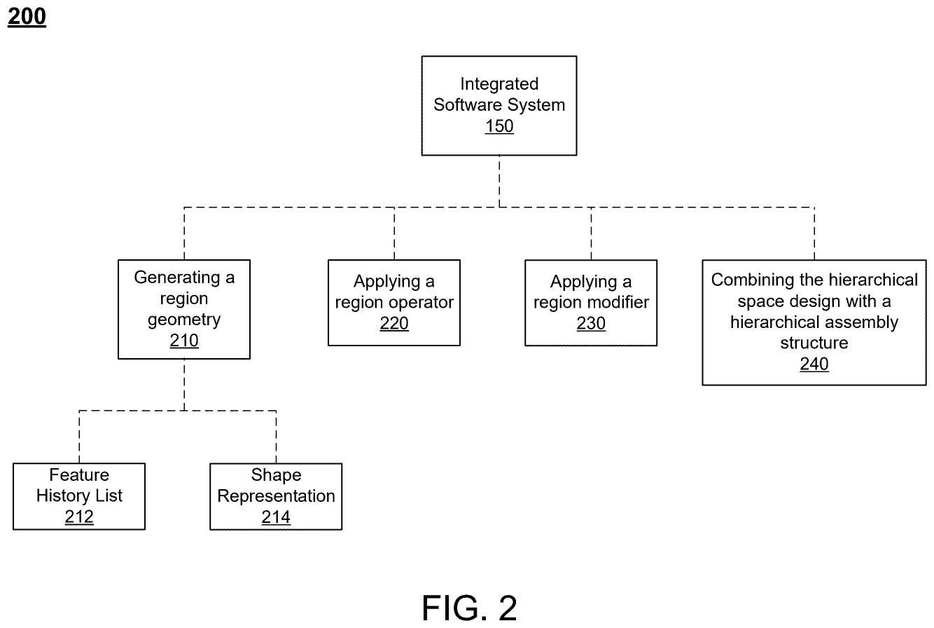

FIG. 2 schematically shows the operation of the integrated software system of FIG. 1 according to certain embodiments of the present invention. As shown in FIG. 2, the integrated software system 150 is used to provide multiple functions, including without being limited to: generating a region geometry 210 for a top-down hierarchical space design, applying a region operator 220, applying a region modifier 230 and combining the hierarchical space design with a hierarchical assembly structure 240.

The region geometry 210 stores the parameters and rules to form the geometric representation of the shape of the corresponding spatial region. In the integrated software system 150, each top-down hierarchical space design may include one or more region geometries 210. For example, the top-down hierarchical space design may include only one region geometry 210, which is the top region geometry of the space design, without any child region geometry. Alternatively, the top-down hierarchical space design may be formed by multiple region geometries 210, which include a first region geometry (i.e., the top region geometry) and at least one second region geometry (i.e., the child region geometry of the top region geometry or another second region geometry). In this case, each child region geometry has a corresponding parent region geometry, and each parent region geometry may have one or more child region geometries. As shown in FIG. 2, each region geometry 210 may include a feature history list 212 and information related to a shape representation 214. The feature history list 212 includes an initial feature of the region geometry 210, and optionally any modified feature(s) of the region geometry if the region geometry 210 has been directly modified by the region modifier 230. In certain embodiments, the shape representation 214 may be a B-rep or other types of shape representation of the region geometry 210.

The region operator 220 is a generative operator which is used to generate one or more child region geometries from a parent region geometry. In the integrated software system 150, one or more region operators 220 may be defined. Specifically, each region operator 220 stores information related to the parameters and rules of the generative operator. In certain embodiments, examples of a region operator 220 may be, without being limited thereto, a horizontal slicer, a vertical slicer, a grid divider, a concentric divider, a scaler, and any other custom defined operators with parameters and rules.

The region modifier 230 is a modifier being applied to modify an existing region geometry 210 and/or an existing region operator 220. Specifically, the region modifier 230, when being applied to modify a region geometry 210 and/or a region operator 220, may be used to change the definition of the region geometry 210 and/or the region operator 220, or may be used to apply additional features to the region geometry 210. In the integrated software system 150, one or more region modifiers 230 may be defined. Specifically, each region modifier 230 stores information related to the parameters and rules for modifying (i.e., changing the definition of, or applying the feature(s) to) the corresponding region geometry 210 and/or the region operator 220.

The hierarchical assembly structure 240 is an assembly formed in a hierarchy, which may include one or a plurality of assemblies. Specifically, in the case where the hierarchical assembly structure 240 includes only one assembly, the assembly is a top assembly without any sub-assembly. On the other hand, when the hierarchical assembly structure 240 includes a plurality of assemblies, the assemblies include a top assembly and at least one sub-assembly and/or part. The top assembly is an assembly formed by all of the sub-assemblies and/or parts, and each sub-assembly may be a sub-assembly of the top assembly or a sub-assembly of another sub-assembly, thus forming the hierarchical assembly structure 240. It should be noted that the formation of the hierarchical assembly structure 240, which may be formed by firstly providing the sub-assemblies and/or parts, and then assembling all of the sub-assemblies to generate the top assembly, is different from the formation of the top-down hierarchical space design, in which the top region geometry is firstly generated before subsequently generating the child region geometries, either generatively or interactively. When combining the top-down hierarchical space design with the hierarchical assembly, either the top assembly and/or zero or any number of sub-assemblies each one is associated to a distinct top region geometry of the top-down hierarchical space design, and the lower-level sub-assemblies are associated to the child region geometries of the distinct top region geometry. However, each distinct top region geometry and its child region geometry must all different from those of other distinct top region geometry.

In certain embodiments, each function of the integrated software system 150 requires a user to input a corresponding instruction to activate the corresponding operation. For example, a user may input instructions to create one or more region geometries 210 for a top-down hierarchical space design, and the integrated software system 150, upon receiving the instructions, generates the region geometries 210. Similarly, the user may input an operator instruction to apply a region operator 220 to a region geometry 210, and the integrated software system 150, upon receiving the operator instruction, applies the region operator 220 to the region geometry 210. In addition, the user may input a modification instruction to apply a region modifier 230 to a region geometry 210 and/or a region operator 220, and the integrated software system 150, upon receiving the modification instruction, applies the region modifier 230. Further, the user may input a combination instruction to combine the top-down hierarchical space design with a hierarchical assembly structure, and the integrated software system 150, upon receiving the combination instruction, performs the combination by associating the sub-assemblies of the hierarchical assembly structure to the region geometries 210 of the top-down hierarchical space design. Alternatively, user may create a top region geometry and associate it to a top assembly or a sub-assembly. Then the user may define and invoke a region operator to apply on the top region geometry and create child region geometry associated with the sub-assembly of the assembly or sub-assembly that is associated with the top region geometry. This process can be repeated as desired.

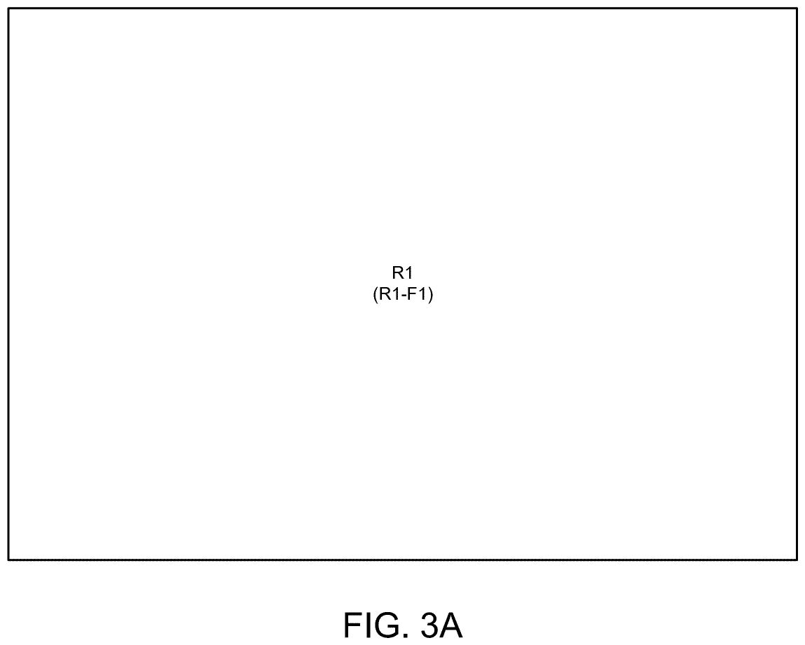

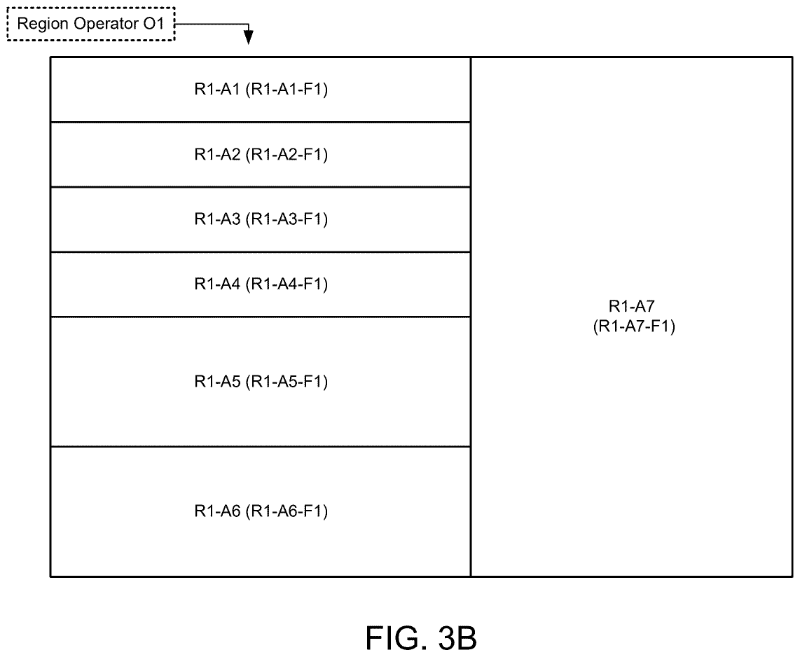

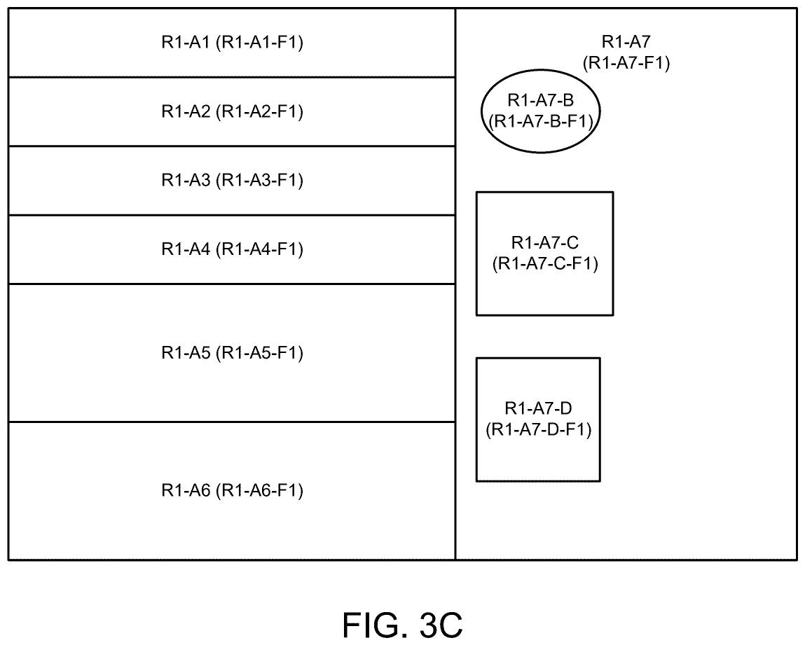

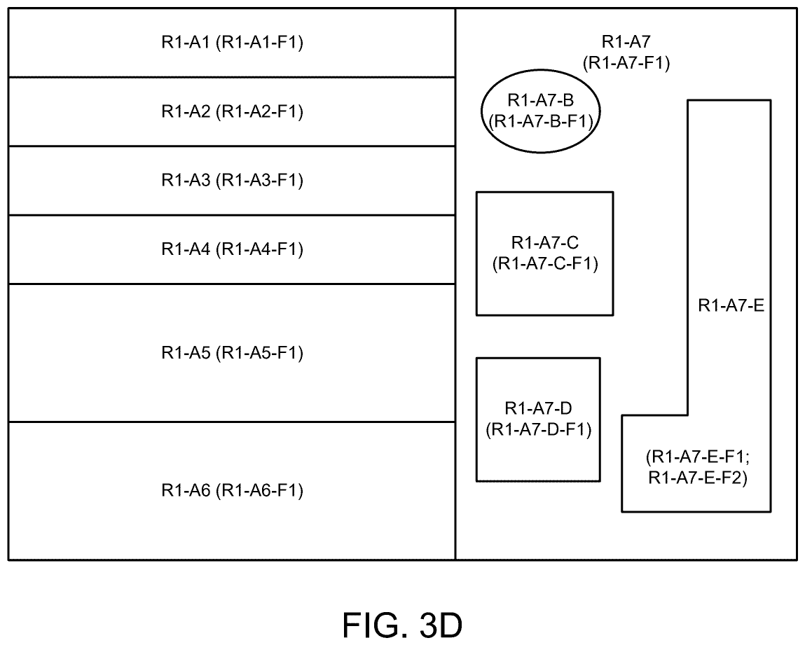

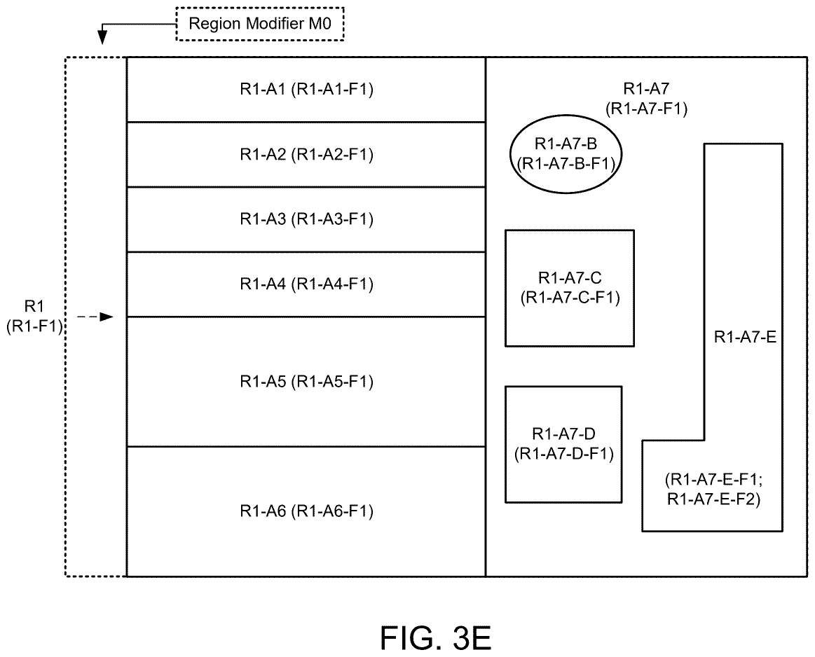

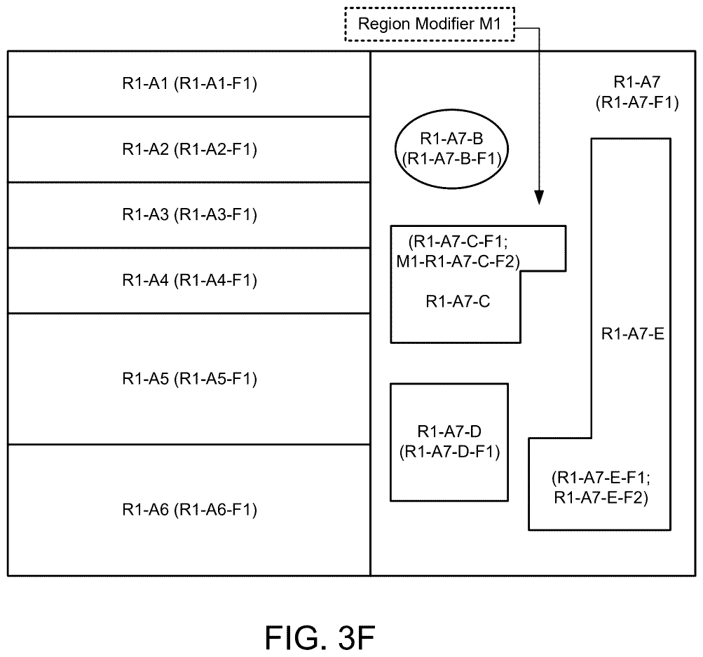

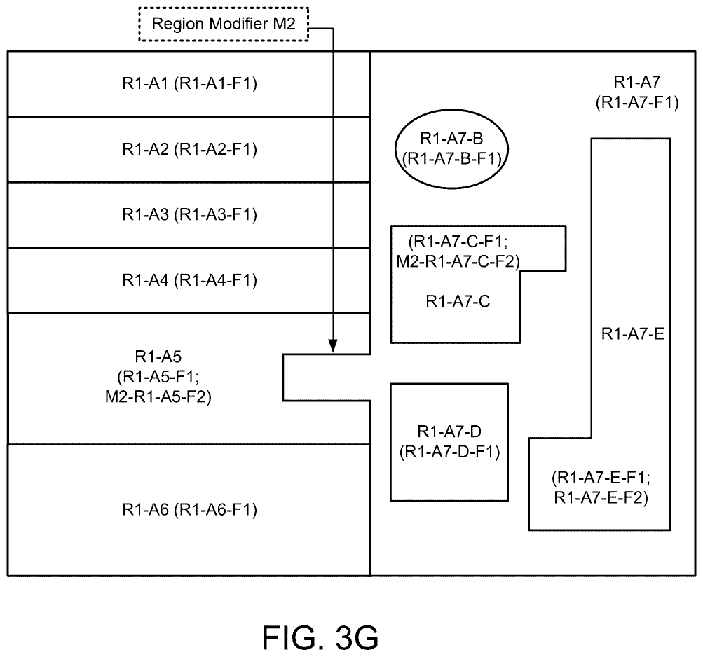

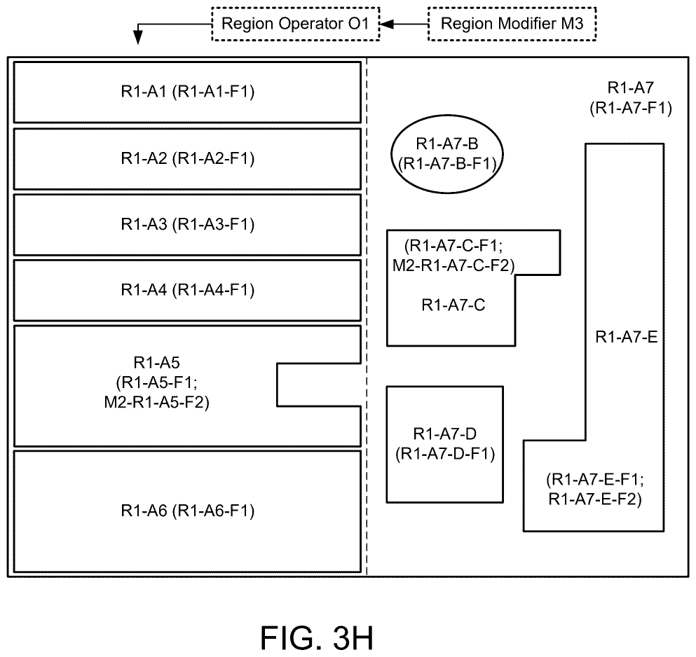

FIGS. 3A to 3H schematically show a process of generating and modifying the region geometries of a top-down hierarchical space design according to certain embodiments of the present invention. Specifically, the top-down hierarchical space design as shown in FIGS. 3A to 3H is a shop floor space design.

As shown in FIG. 3A, when the integrated software system 150 receives an instruction to create a first region geometry (i.e., the top region geometry), the system 150 generates the first region geometry R1. Specifically, the first region geometry R1 is in a rectangular shape, representing the spatial shape of the shop floor space. Thus, the user may start generating subsequent child region geometries of the first region geometry R1, either generatively by applying a region operator or interactively by a manual instruction provided by the user. As shown in FIG. 3A, the feature history list of the top region geometry R1 is shown in the parenthesis. For example, for the top region geometry R1, the feature history list includes its initial feature R1-F1.

Then, as shown in FIG. 3B, the integrated software system 150 receives instructions to create child region geometries on the first region geometry R1, and correspondingly generates the child region geometries according to the instructions. Specifically, the user may input an operator instruction to apply a region operator O1 to the first region geometry R1 for creating a set of child region geometries, and sequentially input a manual instruction to create another child region geometry. Upon receiving the operator instruction and the manual instruction, the integrated software system 150 correspondingly applies the region operator O1 to the first region geometry R1 according to the operator instruction to generate corresponding child region geometries generatively, and then interactively generates the corresponding child region geometry according to the manual instruction. In this way, the integrated software system 150 adopts a combined approach of generative design and interactive design, allowing the user to input two different types of instructions to create the region geometries generatively or interactively. As shown in FIG. 3B, the region operator O1 is defined as a horizontal slicer, which is used to divide the left portion of the first region geometry R1 into 6 horizontal child region geometries (R1-A1, R1-A2, R1-A3, R1-A4, R1-A5, R1-A6) with relative heights of 1:1:1:1:2:2. Then, another child region geometry R1-A7 is generated interactively according to the manual instruction to represent the right portion of the first region geometry R1. Specifically, the child region geometry R1-A7 may be generated to have a fixed width, which is the width of the right portion of the first region geometry R1 not occupied by the horizontal child region geometries R1-A1 to R1-A6.

In certain embodiments, in order to apply the region operator O1 to the first region geometry R1, the user may firstly define the region operator O1 by inputting an operator definition instruction with the parameters and rules to the integrated software system 150. The integrated software system 150, upon receiving the operator definition instruction, defines the region operator O1 according to the operator definition instruction. When the user inputs the operator definition instruction, the user may include all the parameters and rules of the region operator O1 to the system 150. For example, the user may input a rule to define the region operator O1 to apply only to the left portion of the corresponding region geometry (in this case, the first region geometry R1), and parameters corresponding to the horizontal slicer, including the number of divisions of the horizontal child region geometries, the height ratios of the horizontal child region geometries, and the width of the horizontal child region geometries. It should be noted that each of the parameters of the region operator O1 may be a variable. For example, as shown in FIG. 3B, the child region geometry R1-A7 may be interactively generated by the manual instruction provided by the user to have a fixed width. Thus, the width of the horizontal child region geometries R1-A1 to R1-A6 may be defined as the width of the first region geometry R1 minus the fixed width of the child region geometry R1-A7. As shown in FIG. 3B, the feature history list of each individual child region geometry is shown in the parenthesis. For example, for the child region geometry R1-A1, the feature history list includes its initial feature R1-A1-F1. Similarly, each of the other child region geometries R1-A2 to R1-A7 has the corresponding feature history list with the corresponding initial feature R1-A2-F1 to R1-A7-F1.

Subsequently, as shown in FIG. 3C, the integrated software system 150 receives additional manual instructions to create three child region geometries on the region geometry R1-A7. Upon receiving the manual instructions, the integrated software system 150 correspondingly generate the child region geometries R1-A7-B, R1-A7-C and R1-A7-D. As shown in FIG. 3C, the child region geometry R1-A7-B is in an oval shape, and the child region geometries R1-A7-C and R1-A7-D are in rectangular shapes with different sizes and ratios. Specifically, each manual instruction includes parameters and rules to define the shape and size of the corresponding child region geometry. In this case, the region geometry R1-A7 is the parent region geometry of the child region geometries R1-A7-B, R1-A7-C and R1-A7-D. Similarly, the feature history list of each individual child region geometry is shown in the parenthesis. For example, each of the child region geometries R1-A7-B, R1-A7-C and R1-A7-D has the corresponding feature history list with the corresponding initial feature R1-A7-B-F1, R1-A7-C-F1 and R1-A7-D-F1.

Then, as shown in FIG. 3D, the integrated software system 150 receives another manual instruction to create one more child region geometry on the region geometry R1-A7. Upon receiving this manual instruction, the integrated software system 150 correspondingly generate the child region geometry R1-A7-E. As shown in FIG. 3D, the child region geometry R1-A7-E is in a complex shape formed by a combination of two rectangles with different sizes and ratios. Thus, the manual instruction for creating the child region geometry R1-A7-E includes parameters and rules to define the shape and size of the corresponding child region geometry. In this case, the region geometry R1-A7 is also the parent region geometry of the child region geometry R1-A7-E. It should be noted that the child region geometry R1-A7-E, due to its initial complex shape, has the corresponding feature history list with the corresponding initial features (R1-A7-E-F1; R1-A7-E-F2) to indicate the complex shape. In this case, a region hierarchy is formed by the top region geometry R1 at the top level, the region geometries R1-A1 to R1-A7 at the intermediate level, and the region geometries R1-A7-B, R1-A7-C, R1-A7-D and R1-A7-E at the lowest level.

It should be noted that, as shown in FIGS. 3C and 3D, the child region geometries R1-A1 to R1-A7 all sit inside their parent region geometry R1, and the child region geometries R1-A7-B, R1-A7-C, R1-A7-D and R1-A7-E all sit inside their parent region geometry R1-A7. However, the child region geometries R1-A1 to R1-A6 are generated by applying the region operator O1 generatively. Thus, by the definition of the region operator O1, the child region geometries R1-A1 to R1-A6 are always located inside their parent region geometry R1. In comparison, the region geometry R1-A7 and its child region geometries R1-A7-B, R1-A7-C, R1-A7-D and R1-A7-E are interactively generated by manual instructions without using a region operator. Thus, these region geometries, which are interactively generated, may be independent from their corresponding parent region geometries. For example, it is possible to configure one or more of the child region geometries R1-A7-B, R1-A7-C, R1-A7-D and R1-A7-E to be partially or completely located outside their parent region geometry R1-A7.

Subsequently, as shown in FIG. 3E, the integrated software system 150 receives a modifier instruction to apply a region modifier M0 on the top region geometry R1 in order to adjust the width of the top region geometry R1. Specifically, the region modifier M0 is used to be applied to the corresponding region geometry (in this case the top region geometry R1) by changing the definition of the top region geometry R1 to adjust its width, such that the width of the top region geometry R1 is reduced. Upon receiving the modifier instruction, the integrated software system 150 applies the region modifier M0 to the top region geometry R1 to modify the top region geometry R1 by changing the definition of the top region geometry R1 to reduce the width of the top region geometry R1. In this case, for the modified top region geometry R1, the feature history list is not updated due to the modification, and remains including only the initial feature (R1-F1), since the modification by the region modifier M0 involves only the change of definition of the top region geometry R1, and there is no additional feature(s) being applied to the top region geometry R1.

It should be noted that, although the region modifier M0 is applied only to the top region geometry R1, the child region geometries R1-A1 to R1-A7 may also be affected. Specifically, as described above, the child region geometry R1-A7 was generated interactively and has a fixed width. Thus, the child region geometry R1-A7 does not depend on the geometry of the region geometry R1 and is thus not affected by the region modifier M0. Similarly, the child region geometries R1-A7-B, R1-A7-C, R1-A7-D and R1-A7-E were also generated interactively and do not depend on the geometry of their parent region geometry R1-A7. Thus, the child region geometries R1-A7-B, R1-A7-C, R1-A7-D and R1-A7-E are also not affected by the region modifier M0. On the other hand, the child region geometries R1-A1 to R1-A6, which were generated by applying the region operator O1 generatively, may be adjusted or updated by reducing their corresponding widths. In certain embodiments, the adjustment to the child region geometries R1-A1 to R1-A6 may be performed by re-applying the region operator O1 to the modified region geometry R1 to generate the modified child region geometries R1-A1 to R1-A6. It should be noted that the “modification” to the child region geometries R1-A1 to R1-A6 are due to the modification to their parent region geometry (i.e., the top region geometry R1), and the child region geometries R1-A1 to R1-A6 are not being directly modified. Thus, the feature history list of each of the child region geometries R1-A1 to R1-A6 remains including only their initial feature (R1-A1-F1) to (R1-A6-F1), and thus is not updated due to the modification by the region modifier M0.

Then, as shown in FIG. 3F, the integrated software system 150 receives another modifier instruction to interactively apply a region modifier M1 on the region geometry R1-A7-C to add an additional space thereon. Upon receiving the modifier instruction, the integrated software system 150 correspondingly applies the region modifier M1 to the region geometry R1-A7-C and prompts to the user to interactively add the additional space, thus changing the shape of the modified region geometry R1-A7-C. In this case, for the modified region geometry R1-A7-C, the feature history list now includes both the initial feature and the modified feature (R1-A7-C-F1; M1-R1-A7-C-F2).

Subsequently, as shown in FIG. 3G, the integrated software system 150 receives a further modifier instruction to interactively apply a region modifier M2 on the region geometry R1-A5 to remove a portion of the space therefrom. Upon receiving the modifier instruction, the integrated software system 150 correspondingly applies the region modifier M2 to the region geometry R1-A5 and prompts to the user to interactively remove the portion of the space, thus changing the shape of the modified region geometry R1-A5. In this case, for the modified region geometry R1-A5, the feature history list now includes both the initial feature and the modified feature (R1-A5-F1; M2-R1-A5-F2).

Finally, as shown in FIG. 3H, the integrated software system 150 receives yet another modifier instruction to apply another region modifier on the region operator O1 to change the scale of the horizontal slicer. Upon receiving the modifier instruction, the integrated software system 150 correspondingly applies a region modifier M3 to the region operator O1 to change the definition of the region operator O1 with the reduced scale of the horizontal slicer, such that the definition of the region operator O1 is changed according to the parameters and rules of the modifier instruction. Thus, the integrated software system 150 re-applies the modified region operator O1 to the top region geometry R1 to generate the modified child region geometries R1-A1 to R1-A6, with the size of the modified child region geometries R1-A1 to R1-A6 being scaled inward after the horizontal slicing. It should be noted that the “modification” to the child region geometries R1-A1 to R1-A6 are due to the modification to the region operator O1 of their parent region geometry (i.e., the top region geometry R1), and the child region geometries R1-A1 to R1-A6 are not being directly modified. Thus, the feature history list of each of the child region geometries R1-A1 to R1-A6 remain unchanged, and the previously modified region geometry R1-A5 maintaining its feature history list with both the initial feature and the modified feature (R1-A5-F1; M2-R1-A5-F2).

In the process as shown in FIGS. 3A to 3H, the procedures of generating a region geometry may be repeated recursively to generate additional child region geometries in the region hierarchy, and the procedures of applying a region operator and applying a region modifier may be performed to change the features of any region geometry in the region hierarchy, thus constructing a multi-level region hierarchy. For each region geometry, the initial feature is always maintained in the feature history list, regardless of whether the region geometry is created either generatively (i.e., by applying a region operator) or interactively. Thus, the user (e.g., a designer) may invoke a region modifier to interactively modify the geometry of any region geometry by applying one or more additional features, and the additional feature(s) being applied will be appended to the initial feature in the feature history list of the corresponding region geometry. The user may also invoke a region modifier to modify or change the definition of any region operator, and in that case the feature history list will not change.

Further, when a parent region geometry and/or a region operator applied to a parent region geometry is modified, the region operator applied to the parent region geometry will be re-applied to update the corresponding child region geometries. If any child region geometry has been previously modified, all of the modified features previously applied to the child region geometry will be re-applied. Thus, all of the previous modifications to any child region geometry after the initial creation of the child region geometry are preserved together with the modification caused by propagating changes from its parent region geometry and/or the region operator applied to the parent region geometry.

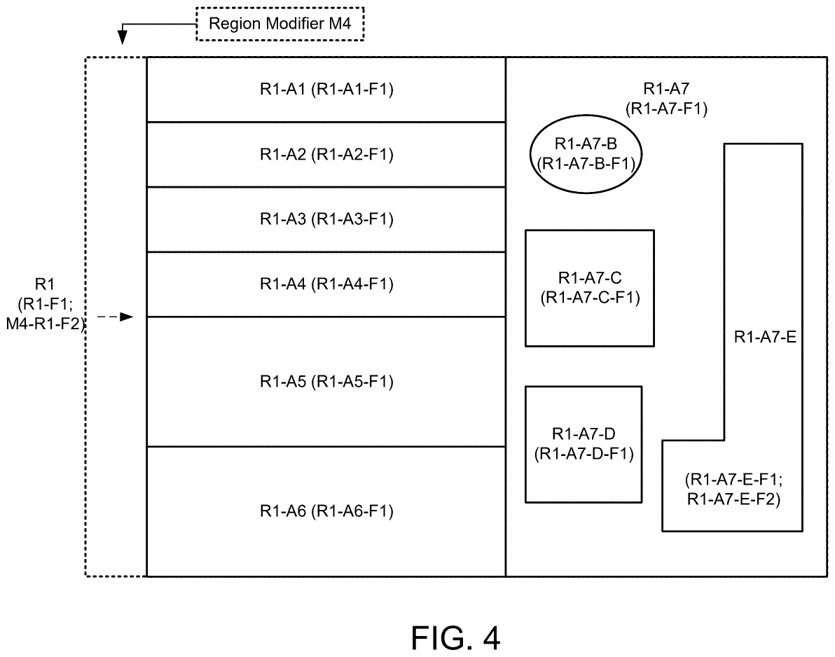

FIG. 4 schematically shows an alternative process of modifying the region geometry of the top-down hierarchical space design from FIG. 3D according to certain embodiments of the present invention. As shown in FIG. 4, the integrated software system 150 receives a modifier instruction to apply a region modifier M4 on the top region geometry R1 in order to remove the portion of the space from the left side of the top region geometry R1. Specifically, the region modifier M4 is used to be applied to the corresponding region geometry (in this case the top region geometry R1) by applying a geometrical feature to the top region geometry R1 (in this case removing the feature on the left side thereof). Upon receiving the modifier instruction, the integrated software system 150 applies the region modifier M4 to the top region geometry R1 to modify the top region geometry R1 by removing the portion of the space at the left side of the top region geometry R1. In this case, for the modified top region geometry R1, the feature history list is updated due to the modification to include both the initial feature and the modified feature (R1-F1; M4-R1-F2).

It should be noted that the region modifier M4 as shown in FIG. 4 is used to apply a geometrical feature on the top region geometry R1 (or more specifically, subtract the geometrical feature from the top region geometry R1) in order to remove the portion of the space from the left side of the top region geometry R1, and the feature history list of the modified top region geometry R1 is updated to append the additional geometrical feature. In comparison, the region modifier M0 as shown in FIG. 3E is used to change the definition of the top region geometry R1 to adjust (or more specifically, to reduce) its width, and the feature history list of the modified top region geometry R1 is not updated. However, the modified top region geometry R1 as shown in each of FIG. 3E and FIG. 4 has the same resulting geometry.

Further, although the region modifier M4 is applied only to the top region geometry R1, the child region geometries R1-A1 to R1-A7 may also be affected. Specifically, as described above, the child region geometry R1-A7 was generated interactively. Thus, the child region geometry R1-A7 does not depend on the geometry of the region geometry R1 and is thus not affected by the region modifier M4. Similarly, the child region geometries R1-A7-B, R1-A7-C, R1-A7-D and R1-A7-E were also generated interactively and do not depend on the geometry of their parent region geometry R1-A7. Thus, the child region geometries R1-A7-B, R1-A7-C, R1-A7-D and R1-A7-E are also not affected by the region modifier M4. On the other hand, the child region geometries R1-A1 to R1-A6, which were generated by applying the region operator O1 generatively, may be adjusted or updated by removing the corresponding space of the top region geometry R1. In certain embodiments, the adjustment to the child region geometries R1-A1 to R1-A6 may be performed by re-applying the region operator O1 to the modified region geometry R1 to generate the modified child region geometries R1-A1 to R1-A6. It should be noted that the “modification” to the child region geometries R1-A1 to R1-A6 are due to the modification to their parent region geometry (i.e., the top region geometry R1), and the child region geometries R1-A1 to R1-A6 are not being directly modified. Thus, the feature history list of each of the child region geometries R1-A1 to R1-A6 remains including only their initial feature (R1-A1-F1) to (R1-A6-F1), and thus is not updated due to the modification by the region modifier M4.

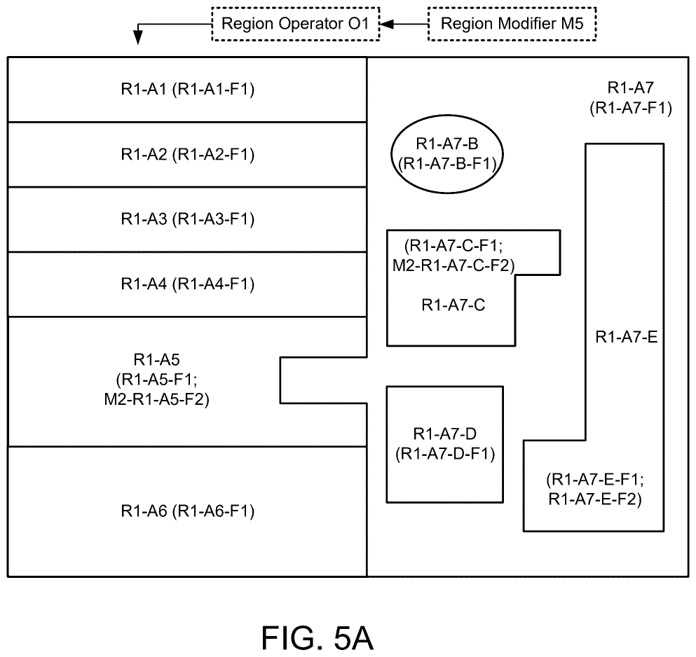

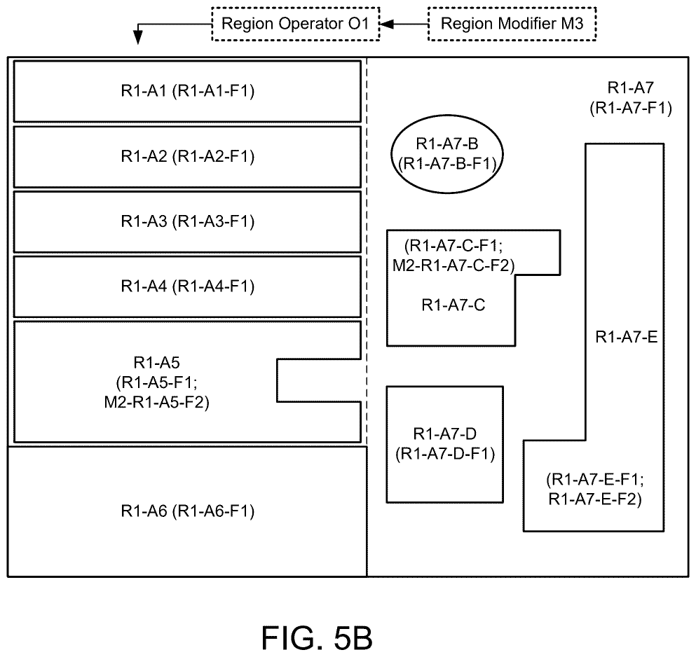

FIGS. 5A and 5B schematically show another alternative process of modifying the region operator and the region geometry of the top-down hierarchical space design from FIG. 3G according to certain embodiments of the present invention. As shown in FIG. 5A, the integrated software system 150 receives a modifier instruction to apply a region modifier M5 on the region operator O1 to change the definition of the region operator O1. Specifically, as described above, the region operator O1 is originally defined as a horizontal slicer, which is used to divide the left portion of the first region geometry R1 into 6 horizontal child region geometries (R1-A1, R1-A2, R1-A3, R1-A4, R1-A5, R1-A6) with relative heights of 1:1:1:1:2:2. The region modifier M5 may change the definition of the horizontal slicer of the region operator O1, such that with the modified definition, only 5 horizontal child region geometries (R1-A1, R1-A2, R1-A3, R1-A4, R1-A5) are formed, and the remaining region originally reserved for the child region geometry R1-A6 is left without a corresponding division. Upon receiving the modifier instruction, the integrated software system 150 correspondingly applies the region modifier M5 to the region operator O1 to change the definition of the region operator O1 to form only 5 horizontal child region geometries (R1-A1, R1-A2, R1-A3, R1-A4, R1-A5). Thus, the integrated software system 150 re-applies the modified region operator O1 to the top region geometry R1 to generate the modified child region geometries R1-A1 to R1-A5. It should be noted that the child region geometry R1-A6, which was originally generated by applying the original region operator O1 generatively, is not re-generated by re-applying the modified region operator O1. Therefore, the child region geometry R1-A6 now becomes independent from its parent region geometry (i.e., the top region geometry R1), which is similar to the other region geometry A1-R7 that was interactively generated by the manual instruction provided by the user. In other words, although the child region geometry R1-A6 was originally generated by applying the original region operator O1 generatively, the modification to the definition of the region operator O1 by the region modifier M5 essentially makes the child region geometry R1-A6 to be similar to a child region geometry being interactively generated, and to be independent from the top region geometry R1.

Then, as shown in FIG. 5B, the integrated software system 150 receives yet another modifier instruction to apply the region modifier M3 on the region operator O1 to change the scale of the horizontal slicer, which is similar to the procedure as shown in FIG. 3H. Upon receiving the modifier instruction, the integrated software system 150 correspondingly applies the region modifier M3 to the region operator O1 to further change the definition of the region operator O1 with the reduced scale of the horizontal slicer, such that the definition of the region operator O1 is changed according to the parameters and rules of the modifier instruction. However, as shown in FIG. 5A, the definition of the region operator O1 has been previously changed due to the modification by the region modifier M5 to form only 5 horizontal child region geometries (R1-A1, R1-A2, R1-A3, R1-A4, R1-A5). Thus, when the integrated software system 150 re-applies the modified region operator O1 to the top region geometry R1, only the modified child region geometries R1-A1 to R1-A5 are generated, with the size of the modified child region geometries R1-A1 to R1-A5 being scaled inward after the horizontal slicing. On the other hand, the child region geometry R1-A6, which is now independent from the top region geometry R1, is not affected by the re-applying of the modified region operator 01.

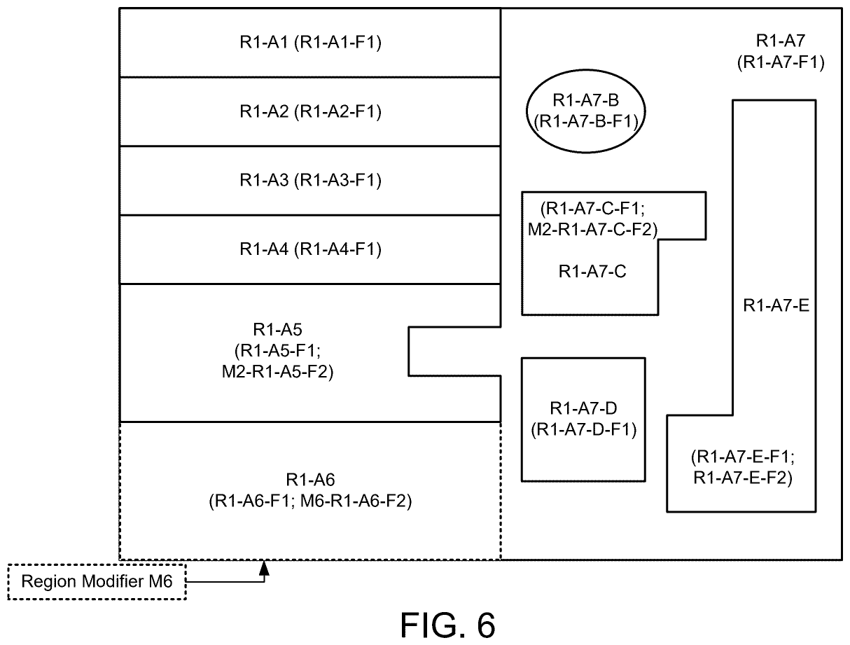

FIG. 6 schematically shows yet another alternative process of modifying the region geometry of the top-down hierarchical space design from FIG. 3G according to certain embodiments of the present invention. As shown in FIG. 6, the integrated software system 150 receives a further modifier instruction to interactively apply a region modifier M6 on the region geometry R1-A6 to remove the whole portion of the space from the region geometry R1-A6. Upon receiving the modifier instruction, the integrated software system 150 correspondingly applies the region modifier M6 to the region geometry R1-A6 and prompt to the user to interactively remove the whole portion of the space, thus removing the whole geometry of the modified region geometry R1-A6. In other words, the modified region geometry R1-A6 still exists, but the modification by the region modifier M6 essentially makes the modified region geometry R1-A6 to occupy no space. In this case, for the modified region geometry R1-A6, the feature history list now includes both the initial feature and the modified feature (R1-A6-F1; M6-R1-A6-F2).

The processes as shown in FIGS. 3A to 3H, FIG. 4, FIG. 5A and FIG. 5B as well as FIG. 6 are merely provided as embodiments of the process of generating and modifying the region geometries. In certain embodiments, the user may apply other region operator(s) and/or region modifier(s) to one of more the region geometries of the top-down hierarchical space design during any stage of the process in order to generate a different region hierarchy.

Once a top-down hierarchical space design is created, the top-down hierarchical space design may be combined with a hierarchical assembly structure to associate the region geometries with the assemblies or sub-assemblies to assist the product design.

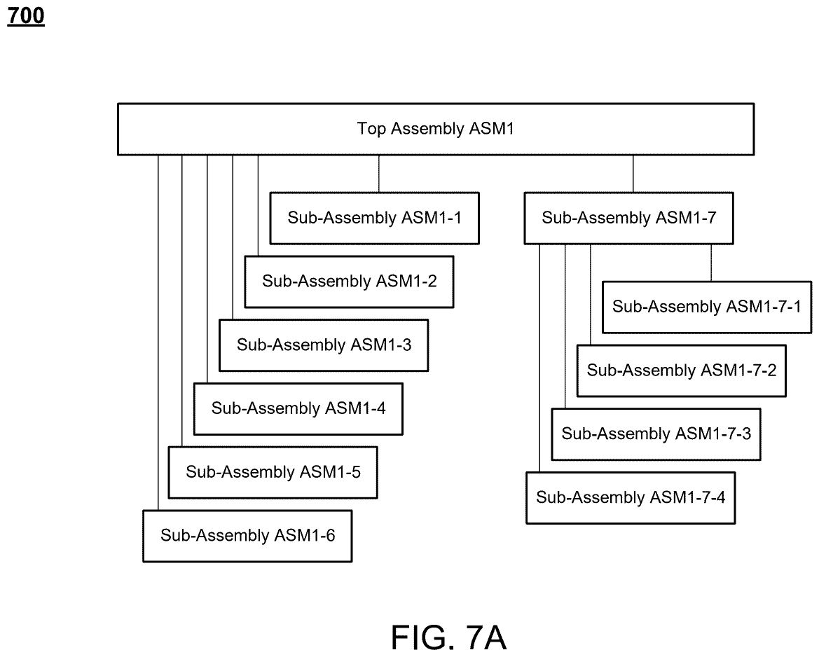

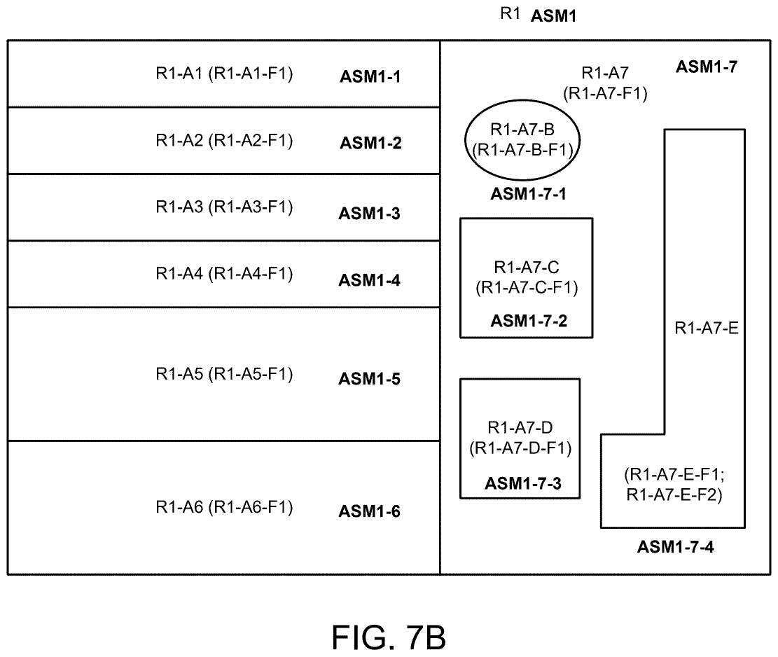

FIG. 7A schematically shows a hierarchical assembly structure according to certain embodiments of the present invention. As shown in FIG. 7A, the hierarchical assembly structure 700 is created for the product design, which is used to be combined with the top-down hierarchical space design as shown in FIGS. 3A to 3H. Specifically, the hierarchical assembly structure 700 includes a top assembly ASM1, which represents the whole shop floor equipment and facilities, and a plurality of sub-assemblies. Specifically, the sub-assemblies includes seven sub-assemblies ASM1-1 to ASM1-7, which are sub-assemblies of the top assembly ASM1, and four additional sub-assemblies ASM1-7-1 to ASM1-7-4, which are sub-assemblies of the sub-assembly ASM1-7. The sub-assemblies ASM1-1 to ASM1-6 represent six storage areas of the shop floor, and the sub-assembly ASM1-7 represents a machine and production line area of the shop floor. In the sub-assembly ASM1-7, the sub-assemblies ASM1-7-1 to ASM1-7-3 represent three machine areas, and the sub-assembly ASM1-7-4 represents a production line area.

FIG. 7B schematically shows combining the top-down hierarchical space design of FIG. 3D with the hierarchical assembly structure of FIG. 7A according to certain embodiments of the present invention. As shown in FIG. 7B, the assembly ASM1 is associated to the top region geometry R1. The sub-assemblies ASM1-1 to ASM1-7 are respectively associated to the region geometries R1-A1 to R1-A7. The sub-assemblies ASM1-7-1, ASM1-7-2, ASM1-7-3 and ASM1-7-4 are respectively associated to the region geometries R1-A7-B, R1-A7-C, R1-A7-D and R1-A7-E.

It should be noted that, after the top-down hierarchical space design is combined with the hierarchical assembly structure, a user may still proceed to further change the top-down hierarchical space design by generating additional region geometries, such that these additional region geometries may be associated with additional sub-assemblies. Alternatively, the user may further apply region operators and/or apply region modifiers to modify and/or update the region geometries. For example, as shown in FIG. 7B, once the top-down hierarchical space design of FIG. 3D is combined with the hierarchical assembly structure of FIG. 7A such that the region geometries are associated with the assemblies, the user (e.g., the designer) may further proceed with the operations as shown in FIGS. 3E to 3H to further change the top-down hierarchical space design, and the corresponding assemblies (e.g., the top assembly and the sub-assemblies) associated with the corresponding modified region geometries may be corresponding adjusted.

In the embodiment as shown in FIG. 7B, the top-down hierarchical space design of FIG. 3D is combined with the hierarchical assembly structure of FIG. 7A such that the region geometries of the top-down hierarchical space design and the assemblies of the hierarchical assembly structure are one-to-one associated to each other. In certain embodiments, however, the combining of the top-down hierarchical space design with a hierarchical assembly structure merely requires that the assemblies of the hierarchical assembly structure to be associated to the region geometries of the top-down hierarchical space design. In certain embodiments, for example, it is possible that the top assembly of a hierarchical assembly structure is associated to a second region geometry instead of the top region geometry of a corresponding top-down hierarchical space design. Alternatively, it is also possible that a top region geometry of a top-down hierarchical space design is associated to a sub-assembly instead of the top assembly of a corresponding hierarchical assembly structure. In certain embodiments, it is possible that a top-down hierarchical space design may be combined with two or more hierarchical assembly structures, with the top assembly of each hierarchical assembly structure being associated to a different region geometry of the top-down hierarchical space design. Alternatively, it is possible that a hierarchical assembly structure may be combined with two or more top-down hierarchical space designs, with the top region geometry of each top-down hierarchical space design being associated to a different assembly of the hierarchical assembly structure.

In certain embodiments, a designer may define relationships between design objects (e.g., parts) contained in an assembly or a sub-assembly and the region geometry associated with that assembly or sub-assembly. Specifically, examples of such relationships may include, without being limited thereto:

### (1) Region Geometry as a Bounding Region

In this case, all design objects shall be within the shape represented by the corresponding region Geometry. Once the region Geometry is modified by any way, or any of its design objects are modified, the integrated software system 150 may automatically perform a bounding box checking or just remind the designer to check.

### (2) Geometry of Design Objects Depending on the Associated Region Geometry of the Owning Assembly/Sub-Assembly

In this case, such relationships can be defined by parameters, rules, or executable procedures. Once the region geometry is modified by any way, the geometries of its owning objects will be automatically updated based on defined relationships.

### (3) Positions of Design Objects Depending on the Associated Region Geometry of the Owning Assembly/Sub-Assembly

In this case, the relationship can be a rigid body relationship, or any parameters, rules, or executable procedures defined position relationships. Once the region geometry is modified by any way, the positions of its owning objects will be automatically updated based on defined relationships.

In certain embodiments, the above-described geometry related dependencies in items (2) and (3) may be combined, i.e., the region geometry may impact both geometries and positions of the design objects.

### (4) Region Geometry as an Influence Region

In this case, the region geometry defines the shape of an influenced space region that design objects within the region shall follow some rules or satisfy certain requirements. For example, a magnetic field influence region requires the design of all objects in the region taking into consideration of magnetic field force. Another example could be a heat influence region requires all objects in the region must have sufficient heat insulation installed and use proper heat resistance material. Sound noise influence region may require using sound absorption material to reduce the impact to people working in such region.

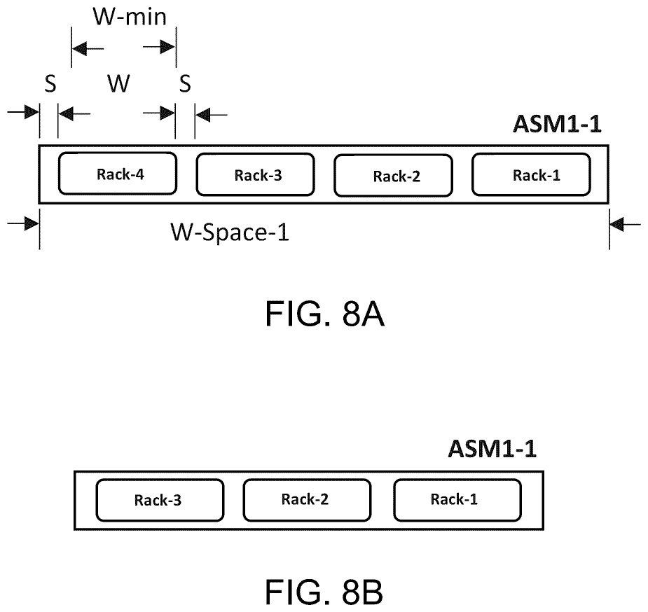

FIGS. 8A and 8B schematically shows the adjustment to a sub-assembly by applying a region modifier to the corresponding region geometry according to certain embodiments of the present invention. Specifically, FIGS. 8A and 8B shows the sub-assembly ASM1-1 as shown in FIG. 7B, which is associated to the region geometry R1-A1.

As shown in FIG. 8A, in the storage sub-assembly ASM1-1, its associated region geometry R1-A1 has a total width W-Space-1. Further, there are four design objects of storage racks (i.e., Rack-1 to Rack-4) in the sub-assembly ASM1-1 with the same width. The gap between the racks is given with a space S. Thus, the width of each storage rack is calculated as W=(W-Space-1-S*5)/4. However, it is also required that the rack width must not be less than a given minimum width of W-min.

As shown in FIG. 8B, when the width of the sub-assembly ASM1-1 is reduced (e.g., due to the region geometry R1-A1 being modified to reduce its width), the rack width W is re-calculated, and in this case, the re-calculated result of the rack width W is less than the minimum width W-min. Therefore, the number of storage racks is reduced, such that only three racks are put in the sub-assembly ASM1-1 instead of four, and the rack width is again re-calculated accordingly as W′=(W-Space-1-S*4)/3, thereby resulting in slightly wider racks.

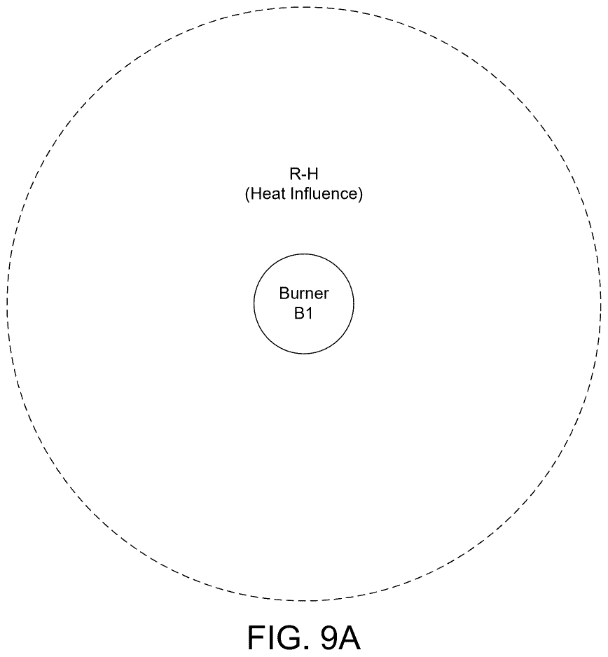

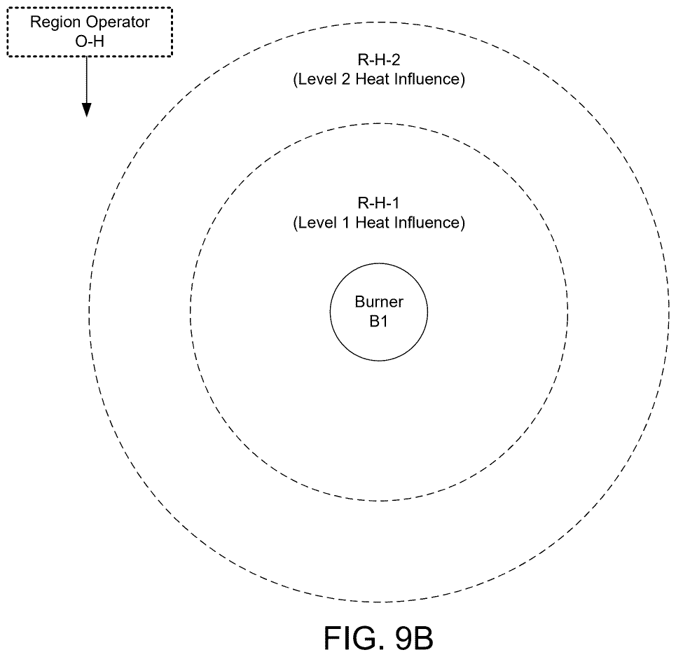

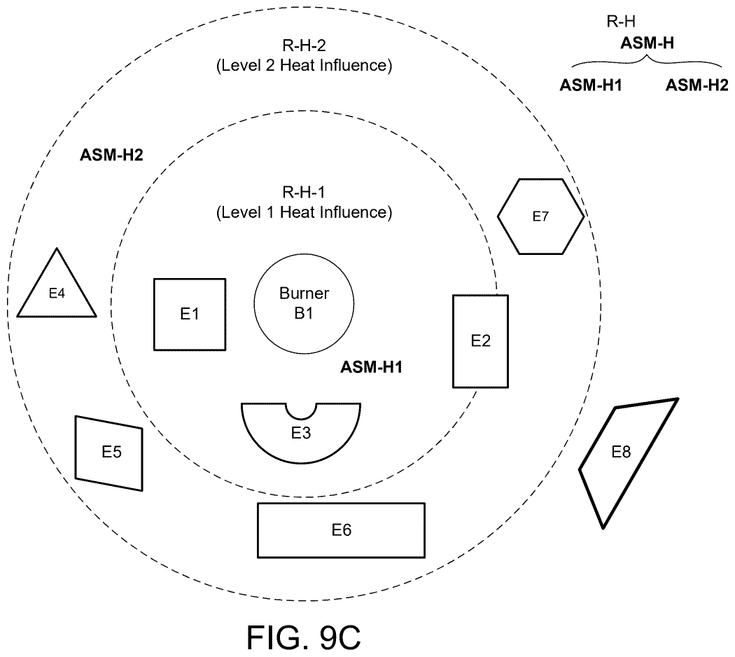

FIGS. 9A to 9C schematically show a process of generating a top-down hierarchical space design combined with a hierarchical assembly structure according to certain embodiments of the present invention. Specifically, the top-down hierarchical space design as shown in FIGS. 9A to 9C is a heat supply facility with a corresponding heat influence region.

As shown in FIG. 9A, in the heat supply facility, a burner B1 is provided to generate very high temperatures in its surrounding area. Therefore, it is required that sufficient heat insulation and proper heat-resistance materials are used for the equipment within those influenced areas. Specifically, FIG. 9A shows the burner B1 and its head influence area, which is represented by a circular region geometry R-H.

As shown in FIG. 9B, a region operator O-H may be applied to divide the circular region geometry R-H into two concentric child region geometries R-H-1 and R-H-2, with two respective levels of heat influence based on the heat transfer gradient. Thus, the inner child region geometry R-H-1 has a level 1 heat influence, and the outer child region geometry R-H-2 has a level 2 heat influence. In this case, the top-down hierarchical space design includes a heat influence region hierarchy, which is formed by the region geometry R-H and its child region geometries R-H-1 and R-H-2.

As shown in FIG. 9C, the heat influence region hierarchy of R-H, R-H-1, R-H-2 is associated with a product design assembly hierarchy of ASM-H, which has two sub-assemblies ASM-H-1 and ASM-H-2, respectively. Specifically, the sub-assembly ASM-H-1 includes three pieces of equipment E1, E2 and E3, and the sub-assembly ASM-H-2 includes five pieces of equipment E4, E5, E6, E7 and E8. In the sub-assembly ASM-H-1, the equipment E1, E2, and E3 are subjected to strong requirements of heat insulation and use high heat resistance materials since they are either inside or overlap with the level 1 heat influence Region Geometry R-H-1, which is associated with the sub-assembly ASM-H1. In the sub-assembly ASM-H-2, the equipment E4, E5, E6 and E7 are subjected to secondary requirements of heat insulation and use relatively lower heat resistance material since they are within the level 2 heat influence region geometry R-H-2, which is associated with the sub-assembly ASM-H-2. It should be noted that, although the equipment E8 belongs to the sub-assembly ASM-H-2, it is located outside the level 2 heat influence region geometry R-H-2. Therefore, the equipment E8 is not subjected to special heat influence requirements.

In certain embodiments, when the design of the burner B1 changes, the peak heat generation may vary. Thus, the heat influence region geometry R-H and its child region geometries R-H-1 and R-H-2 may change accordingly. Consequently, the special design requirements may vary as well.

In certain embodiments, a process of associating a hierarchical assembly structure to a top-down hierarchical space design may be performed to assist product design. Specifically, a starting region geometry may be created and associated with an assembly or sub-assembly at any level of a product design assembly hierarchical structure. If desired, a corresponding region operator may be defined to associated with the starting region geometry. This region operator will, based on the starting region geometry, generate one or more child region geometries associated with one or more sub-assemblies of the assembly (or sub-assembly) which is associated with the starting region geometry. Alternatively, the child region geometries may be interactively created for one or more sub-assemblies of the assembly (or sub-assembly) which is associated with the starting region geometry without the region operator. The procedures can be repeated to one or more child region geometries recursively to construct a multi-level region hierarchy associated with corresponding assembly hierarchy. Further, the procedures can be repeated by creating another starting region geometry at a different location of the product design assembly hierarchical structure. However, any newly created region hierarchy from a new starting region geometry cannot overlap with any existing region hierarchy.

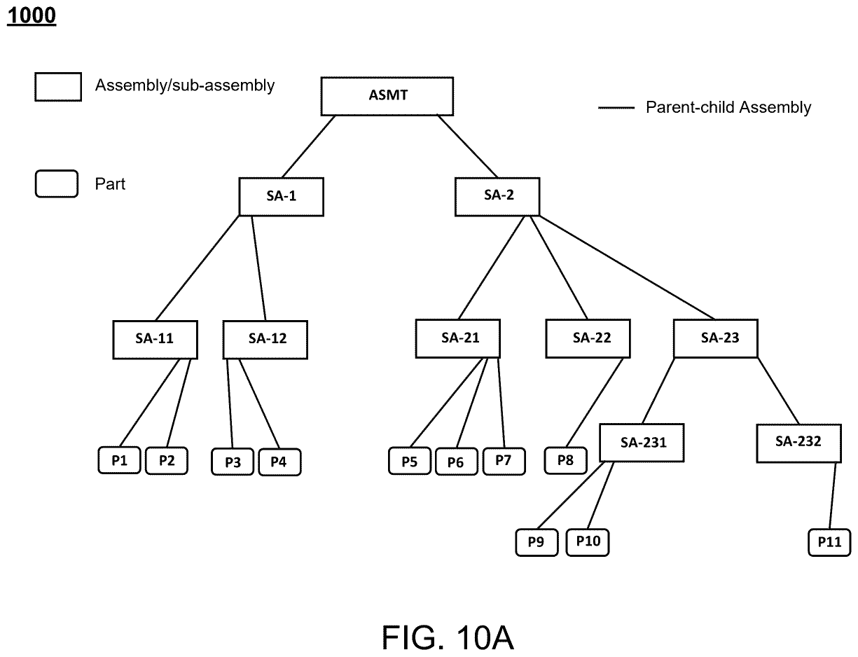

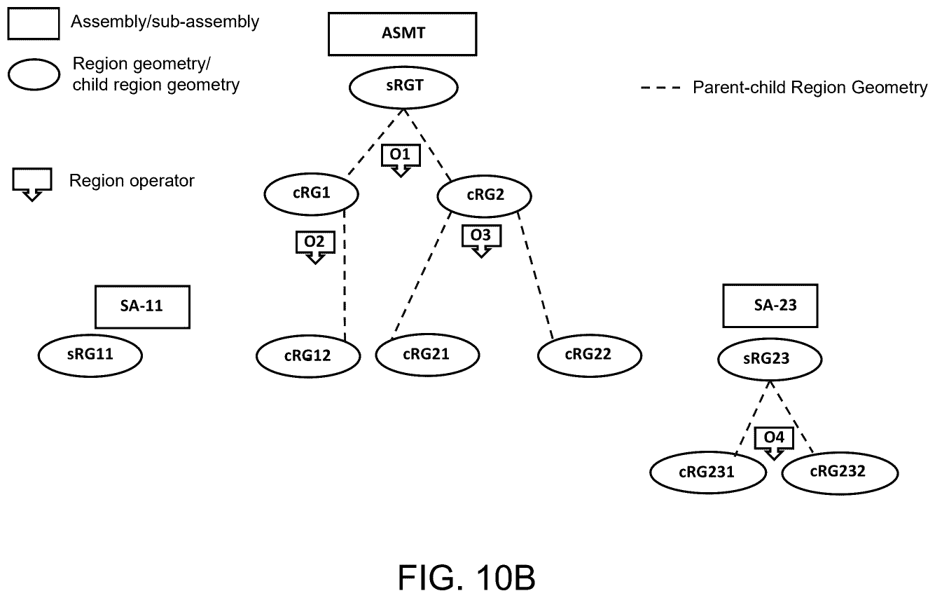

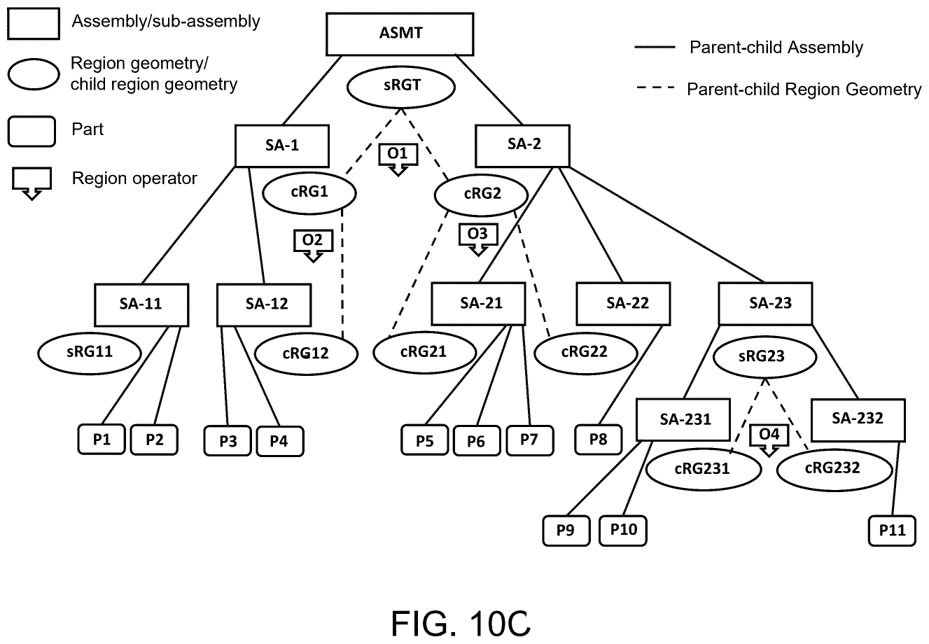

FIGS. 10A to 10C schematically show a process of associating a hierarchical assembly structure to multiple top-down hierarchical space designs according to certain embodiments of the present invention. Specifically, the example process of FIGS. 10A to 10C is provided to demonstrate multiple ways of associating the region geometries of multiple top-down hierarchical space designs with a hierarchical assembly structure.

As shown in FIG. 10A, a hierarchical assembly structure 1000 is provided. In the hierarchical assembly structure 1000, the top assembly ASMT has two sub-assemblies SA-1 and SA-2, which respectively have sub-assemblies SA-11, SA-12, SA-21, SA-22 and SA-23. The sub-assembly SA-23 further includes sub-assemblies SA-231 and SA-232. Each of the lowest level sub-assemblies (i.e., SA-11, SA-12, SA-21, SA-22, SA-231 and SA-232) contains parts to be designed.

As described above, one or more starting region geometry can be created and associated with one or more assembly or sub-assembly at different locations of a product design assembly hierarchical structure. To assist the product design, a user may create several region geometries, and associate them to the assembly and/or sub-assemblies to facilitate the top-down design as well as influence product design.

As shown in FIG. 10B, three starting region geometries sRGT, sRG11 and sRG23 are created to associate with the top assembly ASMT and the two sub-assemblies SA-11 and SA-23, respectively. Specifically, the starting region geometry sRGT is associated with the top assembly ASMT, the starting region geometry sRG11 is associated with the sub-assembly SA-11, and the starting region geometry sRG23 is associated with the sub-assembly SA-23. The hierarchical structures of the starting region geometry sRGT and the starting region geometry sRG23 are also illustrated. Specifically, for the starting region geometry sRGT, a region operator O1 is applied to the starting region geometry sRGT to create two child region geometries cRG1 and cRG2. A region operator O2 is applied to the region geometry cRG1 to create a child region geometry cRG12. A region operator O3 is applied to the region geometry cRG2 to create two child region geometries cRG21 and cRG22. For the starting region geometry sRG23, a region operator O4 is applied to the starting region geometry sRG23 to create two child region geometries cRG231 and cRG232. For the starting region geometry sRG11, there is no child region geometry. In this case, the three starting region geometries sRGT, sRG11 and sRG23 respectively form three individual top-down hierarchical space designs to be combined with the hierarchical assembly structure 1000.

FIG. 10C shows the combined assembly hierarchical structure with the region geometry hierarchical structure. As shown in FIG. 10C, the starting region geometry sRGT is associated to the top assembly ASMT, the two child region geometries cRG1 and cRG2 are respectively associated to the sub-assemblies SA-1 and SA-2, the child region geometry cRG12 is associated to the sub-assembly SA-12, and the child region geometries cRG21 and cRG22 are respectively associated to the sub-assemblies SA-21 and SA-22. The starting region geometry sRG11, which is a standalone region geometry, is associated to the sub-assembly SA-11. The starting region geometry sRG23 is associated to the sub-assembly SA-23, and its two child region geometries cRG231 and cRG232 are respectively associated to the sub-assemblies SA-231 and SA-232.

In the embodiment as shown in FIG. 10C, there are three top-down hierarchical space designs being provided to be combined with the hierarchical assembly structure 1000, such that each of the assemblies of the hierarchical assembly structure is associated to a corresponding region geometry of one of the top-down hierarchical space designs. In certain embodiments, it is possible that a hierarchical assembly structure may be combined with one or more top-down hierarchical space designs, with some of the region geometries of one or more of the top-down hierarchical space designs not being associated to any of the assemblies of the hierarchical assembly structure, or some of the assemblies of the hierarchical assembly structure not being associated to any of the region geometries of one or more of the top-down hierarchical space designs. In certain embodiments, it is also possible that a top-down hierarchical space design may be combined with one or more hierarchical assembly structures, with some of the region geometries of the top-down hierarchical space design not being associated to any of the assemblies of one or more of the hierarchical assembly structures, or some of the assemblies of one or more of the hierarchical assembly structures not being associated to any of the region geometries of the top-down hierarchical space design.

In sum, certain aspects of the present invention relate to an integrated software system that provides a combination of generative design and interactive design methods with comprehensive data structure to facilitate top-down space design together with product design in a CAD system. In this system, a spatial region has a region geometry representing its shape. In certain embodiments, a region geometry may keep a parent-child region hierarchy and provides various generative tools to create all or some child region geometries from the parent region geometry automatically. Alternatively, a child region geometry may also be created interactively and completely independent from its parent region geometry. Modifications to a region geometry may be accomplished by direct modifications or changing its parent/ancestor region geometry or generative tool, and then automatically propagating the changes downward. Due to the comprehensive data structure, both the direct modifications to the region geometry and the propagated changes through generative approach, or any mix of them, are all preserved.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the invention pertains without departing from its spirit and scope. Accordingly, the scope of the invention is defined by the appended claims rather than the foregoing description and the exemplary embodiments described therein.

What is claimed is:

1. A computer-implemented method of generating a top-down hierarchical space design on an integrated system with computer-aided design (CAD) software, the method comprising:
receiving instructions to create a plurality of region geometries of the top-down hierarchical space design;
generating the region geometries according to the instructions;
receiving a modification instruction to apply a region modifier to a corresponding one of the region geometries; and
modifying the corresponding one of the region geometries according to the modification instruction to generate a modified region geometry;
wherein the region geometries include a first region geometry and at least one second region geometry, the first region geometry represents a top-level space in the top-down hierarchical space design, each of the at least one second region geometry is a child region geometry of a parent region geometry, and the parent region geometry is the top region geometry or another one of the at least one second region geometry.

2. The computer-implemented method of claim 1, wherein a specific region geometry of the region geometries comprises:
a feature history list including an initial feature of the specific region geometry, and
information related to a shape representation of the specific region geometry.

3. The computer-implemented method of claim 2, wherein the shape representation of the specific region geometry is a boundary representation (B-rep).

4. The computer-implemented method of claim 2, wherein the region modifier, when being applied to the corresponding one of the region geometries, is configured to apply a geometrical feature to the corresponding one of the region geometries to generate the modified region geometry.

5. The computer-implemented method of claim 4, further comprising:
updating the feature history list of the modified region geometry by appending the geometrical feature to the feature history list of the corresponding one of the region geometries;
wherein for the modified region geometry, the initial feature and the appended geometrical feature are preserved in the updated feature history list.

6. The computer-implemented method of claim 2, wherein the region modifier, when being applied to the corresponding one of the region geometries, is configured to change a definition of the corresponding one of the region geometries to generate the modified region geometry, and the feature history list of the modified region geometry is not updated.

7. The computer-implemented method of claim 1, wherein the child region geometry is generatively generated by:
receiving an operator instruction to apply a region operator to the parent region geometry; and
applying the region operator to the parent region geometry to generate the child region geometry.

8. The computer-implemented method of claim 7, further comprising:
receiving an operator definition instruction to define the region operator; and
defining the region operator according to the operator definition instruction.

9. The computer-implemented method of claim 7, wherein the region operator is:
a horizontal slicer,
a vertical slicer,
a grid divider,
a concentric divider,
a scaler, or
a custom-defined operator.

10. The computer-implemented method of claim 7, further comprising:
receiving the modification instruction to apply the region modifier to the region operator; and
modifying the region operator according to the modification instruction to generate a modified region operator.

11. The computer-implemented method of claim 10 further comprising:
re-applying the modified region operator to the parent region geometry to generate the modified child region geometry.

12. The computer-implemented method of claim 7, further comprising:
receiving the modification instruction to apply the region modifier to the child region geometry; and
modifying the child region geometry according to the modification instruction to generate a modified child region geometry.

13. The computer-implemented method of claim 12, wherein the region modifier is configured to apply a geometrical feature to the child region geometry to generate the modified child region geometry.

14. The computer-implemented method of claim 13, further comprising:
updating the feature history list of the modified child region geometry by appending the geometrical feature to the feature history list of the child region geometry;
wherein for the modified child region geometry, the initial feature and the appended geometrical feature are preserved in the updated feature history list.

15. The computer-implemented method of claim 7, further comprising:
receiving the modification instruction to apply the region modifier to the parent region geometry;
modifying the parent region geometry according to the modification instruction to generate a modified parent region geometry; and
re-applying the region operator to the modified parent region geometry to generate a modified child region geometry.

16. The computer-implemented method of claim 15, wherein the region modifier is configured to apply a geometrical feature to the parent region geometry to generate the modified parent region geometry.

17. The computer-implemented method of claim 16, further comprising:
updating the feature history list of the modified parent region geometry by appending the geometrical feature to the feature history list of the parent region geometry;
wherein for the modified parent region geometry, the initial feature and the appended geometrical feature are preserved in the updated feature history list.

18. The computer-implemented method of claim 15, wherein the region modifier is configured to change a definition of the parent region geometry to generate the modified parent region geometry, and the feature history list of the modified parent region geometry and the feature history list of the modified child region geometry are not updated.

19. The computer-implemented method of claim 1, wherein each of the first region geometry and the child region geometry is interactively generated based on a manual instruction provided by a user.

20. The computer-implemented method of claim 19, further comprising:
receiving the modification instruction to apply the region modifier to the parent region geometry; and
modifying the parent region geometry according to the modification instruction to generate a modified parent region geometry;
wherein the child region geometry being interactively generated is not updated according to the modification instruction to the parent region geometry.

21. The computer-implemented method of claim 19, further comprising:
receiving the modification instruction to apply the region modifier to the child region geometry; and
modifying the child region geometry according to the modification instruction to generate a modified child region geometry.

22. The computer-implemented method of claim 21, wherein the region modifier is configured to apply a geometrical feature to the child region geometry to generate the modified child region geometry.

23. The computer-implemented method of claim 22, further comprising:
updating the feature history list of the modified child region geometry by appending the geometrical feature to the feature history list of the child region geometry,
wherein for the modified child region geometry, the initial feature and the appended geometrical feature are preserved in the updated feature history list.

24. The computer-implemented method of claim 19, wherein the region modifier is configured to change a definition of the child region geometry to generate the modified child region geometry, and the feature history list of the modified child region geometry is not updated.

25. The computer-implemented method of claim 19, further comprising:
receiving the modification instruction to apply the region modifier to the top region geometry; and
modifying the top region geometry according to the modification instruction to generate a modified top region geometry.

26. The computer-implemented method of claim 25, wherein the region modifier is configured to apply a geometrical feature to the top region geometry to generate the modified top region geometry.

27. The computer-implemented method of claim 26, further comprising:
updating the feature history list of the modified top region geometry by appending the geometrical feature to the feature history list of the top region geometry,
wherein for the modified top region geometry, the initial feature and the appended geometrical feature are preserved in the updated feature history list.

28. The computer-implemented method of claim 25, wherein the region modifier is configured to change a definition of the top region geometry to generate the modified top region geometry, and the feature history list of the modified top region geometry is not updated.

29. The computer-implemented method of claim 1, further comprising:
combining the top-down hierarchical space design with a hierarchical assembly structure,
wherein the hierarchical assembly structure includes a plurality of assemblies, the assemblies include a top assembly and at least one sub-assembly, and the assemblies of the hierarchical assembly structure are associated to the region geometries of the top-down hierarchical space design.

30. The computer-implemented method of claim 29, further comprising:
in response to modifying the corresponding one of the region geometries according to the modification instruction, adjusting a corresponding assembly of the assemblies of the hierarchical assembly structure associated with the corresponding one of the region geometries according to the modified region geometry.

31. The computer-implemented method of claim 29, further comprising:
defining a relationship between design objects contained in a corresponding assembly of the assemblies of the hierarchical assembly structure and the corresponding one of the region geometries associated with the corresponding assembly.

32. The computer-implemented method of claim 31, wherein the relationship between the design objects contained in the corresponding assembly and the corresponding one of the region geometries associated with the corresponding assembly includes:
defining the corresponding one of the region geometries associated with the corresponding assembly as a bounding region of the design objects;
defining a geometry of the design objects to depend on the corresponding one of the region geometries associated with the corresponding assembly;
defining positions of the design objects to depend on the corresponding one of the region geometries associated with the corresponding assembly; or
defining the corresponding one of the region geometries associated with the corresponding assembly as an influence region of the design objects.

33. The computer-implemented method of claim 31, further comprising:
in response to modifying the corresponding one of the region geometries associated with the corresponding assembly according to the modification instruction, adjusting the corresponding assembly and the design objects contained in the corresponding assembly according to the modified region geometry.

34. The computer-implemented method of claim 29, wherein the first region geometry of the top-down hierarchical space design is associated to the top assembly or a corresponding sub-assembly of the assemblies of the hierarchical assembly structure.

35. The computer-implemented method of claim 29, wherein the top assembly of the hierarchical assembly structure is associated to the first region geometry or a corresponding second region geometry of the region geometries of the top-down hierarchical space design.

36. An integrated system with computer-aided design (CAD) software, comprising:
a processor; and
a storage device storing computer executable code,
wherein the computer executable code, when executed at the processor, is configured to provide the CAD software, and to:
receive instructions to create a plurality of region geometries of a top-down hierarchical space design;
generate the region geometries according to the instructions;
receive a modification instruction to apply a region modifier to a corresponding one of the region geometries; and
modify the corresponding one of the region geometries according to the modification instruction to generate a modified region geometry;
wherein the region geometries include a first region geometry and at least one second region geometry, the first region geometry represents a top-level space in the top-down hierarchical space design, each of the at least one second region geometry is a child region geometry of a parent region geometry, and the parent region geometry is the top region geometry or another one of the at least one second region geometry.

37. The integrated system of claim 36, wherein a specific region geometry of the region geometries comprises:
a feature history list including an initial feature of the specific region geometry, and
information related to a shape representation of the specific region geometry.

38. The integrated system of claim 37, wherein the shape representation of the specific region geometry is a boundary representation (B-rep).

39. The integrated system of claim 37, wherein the region modifier, when being applied to the corresponding one of the region geometries, is configured to apply a geometrical feature to the corresponding one of the region geometries to generate the modified region geometry.

40. The integrated system of claim 39, wherein the computer executable code, when executed at the processor, is further configured to:
update the feature history list of the modified region geometry by appending the geometrical feature to the feature history list of the corresponding one of the region geometries;
wherein for the modified region geometry, the initial feature and the appended geometrical feature are preserved in the updated feature history list.

41. The integrated system of claim 37, wherein the region modifier, when being applied to the corresponding one of the region geometries, is configured to change a definition of the corresponding one of the region geometries to generate the modified region geometry, and the feature history list of the modified region geometry is not updated.

42. The integrated system of claim 36, wherein the child region geometry is generatively generated by:
receiving an operator instruction to apply a region operator to the parent region geometry; and
applying the region operator to the parent region geometry to generate the child region geometry.

43. The integrated system of claim 42, wherein the computer executable code, when executed at the processor, is further configured to:
receive an operator definition instruction to define the region operator; and
define the region operator according to the operator definition instruction.

44. The integrated system of claim 42, wherein the region operator is:
a horizontal slicer,
a vertical slicer,
a grid divider,
a concentric divider,
a scaler, or
a custom-defined operator.

45. The integrated system of claim 42, wherein the computer executable code, when executed at the processor, is further configured to:
receive the modification instruction to apply the region modifier to the region operator; and
modifying the region operator according to the modification instruction to generate a modified region operator.

46. The integrated system of claim 45, wherein the computer executable code, when executed at the processor, is further configured to:
re-apply the modified region operator to the parent region geometry to generate the modified child region geometry.

47. The integrated system of claim 42, wherein the computer executable code, when executed at the processor, is further configured to:
receive the modification instruction to apply the region modifier to the child region geometry; and
modify the child region geometry according to the modification instruction to generate a modified child region geometry.

48. The integrated system of claim 47, wherein the region modifier is configured to apply a geometrical feature to the child region geometry to generate the modified child region geometry.

49. The integrated system of claim 48, wherein the computer executable code, when executed at the processor, is further configured to:
update the feature history list of the modified child region geometry by appending the geometrical feature to the feature history list of the child region geometry;
wherein for the modified child region geometry, the initial feature and the appended geometrical feature are preserved in the updated feature history list.

50. The integrated system of claim 42, wherein the computer executable code, when executed at the processor, is further configured to:
receive the modification instruction to apply the region modifier to the parent region geometry;
modify the parent region geometry according to the modification instruction to generate a modified parent region geometry; and
re-apply the region operator to the modified parent region geometry to generate a modified child region geometry.

51. The integrated system of claim 50, wherein the region modifier is configured to apply a geometrical feature to the parent region geometry to generate the modified parent region geometry.

52. The integrated system of claim 51, wherein the computer executable code, when executed at the processor, is further configured to:
update the feature history list of the modified parent region geometry by appending the geometrical feature to the feature history list of the parent region geometry;
wherein for the modified parent region geometry, the initial feature and the appended geometrical feature are preserved in the updated feature history list.

53. The integrated system of claim 50, wherein the region modifier is configured to change a definition of the parent region geometry to generate the modified parent region geometry, and the feature history list of the modified parent region geometry and the feature history list of the modified child region geometry are not updated.

54. The integrated system of claim 36, wherein each of the first region geometry and the child region geometry is interactively generated based on a manual instruction provided by a user.

55. The integrated system of claim 54, wherein the computer executable code, when executed at the processor, is further configured to:
receive the modification instruction to apply the region modifier to the parent region geometry; and
modify the parent region geometry according to the modification instruction to generate a modified parent region geometry;
wherein the child region geometry being interactively generated is not updated according to the modification instruction to the parent region geometry.

56. The integrated system of claim 54, wherein the computer executable code, when executed at the processor, is further configured to:
receive the modification instruction to apply the region modifier to the child region geometry; and
modify the child region geometry according to the modification instruction to generate a modified child region geometry.

57. The integrated system of claim 56, wherein the region modifier is configured to apply a geometrical feature to the child region geometry to generate the modified child region geometry.

58. The integrated system of claim 57, wherein the computer executable code, when executed at the processor, is further configured to:
update the feature history list of the modified child region geometry by appending the geometrical feature to the feature history list of the child region geometry,
wherein for the modified child region geometry, the initial feature and the appended geometrical feature are preserved in the updated feature history list.

59. The integrated system of claim 54, wherein the region modifier is configured to change a definition of the child region geometry to generate the modified child region geometry, and the feature history list of the modified child region geometry is not updated.

60. The integrated system of claim 54, wherein the computer executable code, when executed at the processor, is further configured to:
receive the modification instruction to apply the region modifier to the top region geometry; and
modify the top region geometry according to the modification instruction to generate a modified top region geometry.

61. The integrated system of claim 60, wherein the region modifier is configured to apply a geometrical feature to the top region geometry to generate the modified top region geometry.

62. The integrated system of claim 61, wherein the computer executable code, when executed at the processor, is further configured to:
update the feature history list of the modified top region geometry by appending the geometrical feature to the feature history list of the top region geometry,
wherein for the modified top region geometry, the initial feature and the appended geometrical feature are preserved in the updated feature history list.

63. The integrated system of claim 60, wherein the region modifier is configured to change a definition of the top region geometry to generate the modified top region geometry, and the feature history list of the modified top region geometry is not updated.

64. The integrated system of claim 36, wherein the computer executable code, when executed at the processor, is further configured to:
combine the top-down hierarchical space design with a hierarchical assembly structure,
wherein the hierarchical assembly structure includes a plurality of assemblies, the assemblies include a top assembly and at least one sub-assembly, and the assemblies of the hierarchical assembly structure are associated to the region geometries of the top-down hierarchical space design.

65. The integrated system of claim 64, wherein the computer executable code, when executed at the processor, is further configured to:
in response to modifying the corresponding one of the region geometries according to the modification instruction, adjust a corresponding assembly of the assemblies of the hierarchical assembly structure associated with the corresponding one of the region geometries according to the modified region geometry.

66. The integrated system of claim 64, wherein the computer executable code, when executed at the processor, is further configured to:
define a relationship between design objects contained in a corresponding assembly of the assemblies of the hierarchical assembly structure and the corresponding one of the region geometries associated with the corresponding assembly.

67. The integrated system of claim 66, wherein the relationship between the design objects contained in the corresponding assembly and the corresponding one of the region geometries associated with the corresponding assembly includes:
defining the corresponding one of the region geometries associated with the corresponding assembly as a bounding region of the design objects;
defining a geometry of the design objects to depend on the corresponding one of the region geometries associated with the corresponding assembly;
defining positions of the design objects to depend on the corresponding one of the region geometries associated with the corresponding assembly; or
defining the corresponding one of the region geometries associated with the corresponding assembly as an influence region of the design objects.

68. The integrated system of claim 66, wherein the computer executable code, when executed at the processor, is further configured to:
in response to modifying the corresponding one of the region geometries associated with the corresponding assembly according to the modification instruction, adjust the corresponding assembly and the design objects contained in the corresponding assembly according to the modified region geometry.

69. The integrated system of claim 64, wherein the first region geometry of the top-down hierarchical space design is associated to the top assembly or a corresponding sub-assembly of the assemblies of the hierarchical assembly structure.

70. The integrated system of claim 64, wherein the top assembly of the hierarchical assembly structure is associated to the first region geometry or a corresponding second region geometry of the region geometries of the top-down hierarchical space design.
